(19) United States
(12) Patent Application Publication
(10) Pub. No.: US 2022/0320225 A1
(43) Pub. Date: Oct. 6, 2022

(54) DISPLAY SUBSTRATE AND METHOD FOR MANUFACTURING THE SAME, AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Pengfei YU, Beijing (CN); Haigang QING, Beijing (CN); Tinghua SHANG, Beijing (CN); Jie DAI, Beijing (CN); Lu BAI, Beijing (CN); Qiang ZHANG, Beijing (CN); Chenxing WAN, Beijing (CN); Yang ZHOU, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 17/298,500

(22) PCT Filed: Aug. 31, 2020
(86) PCT No.: PCT/CN2020/112676

§ 371 Date: May 28, 2021

(51) Int. Cl. H01L 27/32

(52) U.S. Cl. CPC H01L 27/3276; H01L 27/3213; H01L 2227/323; G06V 40/1318

(57) ABSTRACT

A display substrate and a method for manufacturing the same, and a display device. Each sub-pixel in the display substrate includes a power signal line pattern. The power signal line pattern includes a first power line portion and a second power line portion; a main body portion of the second power line portion and the first power line portion are arranged in a first direction and are spaced apart from each other; a first end portion of the second power line portion is respectively coupled with one end of the main body portion and the first power line portion; the second end portion is respectively coupled with the other end of the main body portion and the first power line portion; an aperture is defined between the first power line portion and the second power line portion.

### TECHNICAL FIELD

The present disclosure relates to the field of display technology, and in particular to a display substrate and a method for manufacturing the same, and a display device.

### BACKGROUND

With continuous development of display technologies, display screens with fingerprint identification function are widely used. Such display screen generally adopts the optical fingerprint recognition technology, which uses the principle of light refraction and reflection to recognize users' fingerprints.

When such display screen is used for fingerprint recognition, a finger is placed on the display screen, and light emitted from an internal light source under an array substrate in the display screen is reflected by uneven grooves on a fingertip to produce light with different reflection angles, so that light intensities received by a sensing element on a back of the display screen are varied, and then different photocurrents are generated. Based on sizes of the photocurrents, a fmgerprint pattern can be detected and recognized via comparison.

### SUMMARY

One purpose of the present disclosure is to provide a display substrate, a method for manufacturing the same, and a display device.

According to a first aspect of the present disclosure, a display substrate is provided and includes: a base substrate and an array of sub-pixels on the base substrate. Each sub-pixel includes a power signal line pattern. The power signal line pattern includes a first power line portion and a second power line portion; at least one part of the first power line portion extends in a second direction; the second power line portion includes a main body portion, a first end portion and a second end portion; the main body portion and the first power line portion are arranged in a first direction and are spaced apart from each other; the first direction intersects the second direction; the first end portion and the second end portion are disposed opposite to each other along the second direction; the first end portion is respectively coupled with one end of the main body portion and the first power line portion; the second end portion is respectively coupled with the other end of the main body portion and the first power line portion; an aperture is defined between the first power line portion and the second power line portion.

Optionally, the sub-pixels are divided into multiple rows of sub-pixels; each row of sub-pixels includes multiple sub-pixels arranged in sequence along the first direction; the sub-pixel further includes: a first data line pattern and a second data line pattern arranged oppositely along the first direction; at least one part of the first data line pattern and at least one part of the second data line pattern extend along the second direction; an orthographic projection of the first data line pattern onto the base substrate, overlaps with an orthographic projection of the first power line portion in one sub-pixel, which is adjacent, in the first direction, to the sub-pixel that the first data line pattern belongs to, onto the base substrate; an orthographic projection of the second data line pattern onto the base substrate overlaps with an orthographic projection of the main body portion onto the base substrate.

Optionally, the orthographic projection of the first data line pattern onto the base substrate does not overlap with an orthographic projection of the aperture onto the base substrate; and/or, the orthographic projection of the second data line pattern onto the base substrate does not overlap with the orthographic projection of the aperture onto the base substrate.

Optionally, the sub-pixel further includes a light-emitting control signal line pattern; at least one part of the light-emitting control signal line pattern extends along the first direction; an orthographic projection of the light-emitting control signal line pattern onto the base substrate partially overlaps with an orthographic projection of the aperture onto the base substrate.

Optionally, the first power line portion includes a second sub-portion and a first sub-portion that encloses the aperture; in a plane parallel to the base substrate and in a direction perpendicular to the second direction, a width of the first sub-portion is less than a width of the second sub-portion.

Optionally, the sub-pixel further includes a light-emitting element; the light-emitting element includes an anode pattern; an orthographic projection of the anode pattern onto the base substrate does not overlap with an orthographic projection of the aperture onto the base substrate.

Optionally, the orthographic projection of the aperture onto the base substrate is between an orthographic projection of a first anode pattern onto the base substrate and an orthographic projection of a second anode pattern onto the base substrate; the sub-pixel to which the aperture belongs, includes the first anode pattern; and a next sub-pixel, which is adjacent to, in the first direction, the sub-pixel to which the aperture belongs, includes the second anode pattern.

Optionally, the sub-pixels are divided into multiple pixel units; each pixel unit includes a red sub-pixel, a blue sub-pixel and two green sub-pixels;

among the pixel units in the same row along the first direction, the anode pattern included in the red sub-pixel in each pixel unit and the anode pattern included in the blue sub-pixel in each pixel unit are distributed in one row; and the anode pattern included in the green sub-pixel in each pixel unit are distributed in another row;

among the pixel units in the same row along the first direction, the anode pattern included in the red sub-pixel, the anode pattern included in the blue sub-pixel and the anode pattern included in the green sub-pixel are alternately distributed in sequence;

among the pixel units in the same row along the first direction, one of adjacent red sub-pixel and green sub-pixel includes the first anode pattern, and the other of the adjacent red sub-pixel and green sub-pixel includes the second anode pattern;

among the pixel units in the same row along the first direction, one of adjacent blue sub-pixel and green sub-pixel includes the first anode pattern, and the other of the adjacent blue sub-pixel and green sub-pixel includes the second anode pattern.

Optionally, the sub-pixel further includes a light-emitting element; the light-emitting element includes an anode pattern; an orthographic projection of some anode patterns onto the base substrate overlaps with an orthographic projection of the aperture onto the base substrate.

Optionally, the main body portion includes a first main body part and a second main body part; the first main body part is close to the first end portion; the second main body part is close to the second end portion; in a plane parallel to the base substrate and in a direction perpendicular to the second direction, a width of the first main body part is greater than a width of the second main body part;

the sub-pixel further includes a sub-pixel driving circuit; the sub-pixel driving circuit includes a driving transistor and a storage capacitor; a first electrode plate of the storage capacitor is coupled with a gate electrode of the driving transistor; there is an overlapping area between an orthographic projection of a second electrode plate of the storage capacitor onto the base substrate and an orthographic projection of the first main body part onto the base substrate; the second electrode plate of the storage capacitor is coupled with the first main body part through a via-hole in the overlapping area.

Optionally, the orthographic projection of the second electrode plate of the storage capacitor onto the base substrate does not overlap with an orthographic projection of the aperture onto the base substrate.

Optionally, he sub-pixel further includes a power compensation pattern; at least one part of the power compensation pattern extends along the first direction; the power compensation pattern is respectively coupled with the main body portion, and the first power line portion of one sub-pixel, which is adjacent, in the first direction, to the sub-pixel to which the power compensation pattern belongs.

Optionally, the sub-pixel further includes: a reset signal line pattern, a gate line pattern, and a light-emitting control signal line pattern, which are sequentially distributed along the second direction; at least one part of the signal line pattern extends along the first direction; at least one part of the gate line pattern extends along the first direction; at least one part of the light-emitting control signal line pattern extends along the first direction; an orthographic projection of the power compensation pattern onto the base substrate is between an orthographic projection of the gate line pattern onto the base substrate and an orthographic projection of the light-emitting control signal line pattern onto the base substrate.

Optionally, the sub-pixel further includes a light-emitting control signal line pattern; at least one part of the light-emitting control signal line pattern extends along the first direction; the light-emitting control signal line pattern includes a first light-emitting control portion and a second light-emitting control portion;

an orthographic projection of the first light-emitting control portion onto the base substrate overlaps with an orthographic projection of the main body portion onto the base substrate, an orthographic projection of the aperture onto the base substrate and an orthographic projection of the first power line portion onto the base substrate, respectively;

in the second direction, an orthographic projection of the second light-emitting control portion onto the base substrate is opposite to an orthographic projection of the power compensation pattern onto the base substrate; in a plane parallel to the base substrate and in a direction perpendicular to the first direction, a width of the second light-emitting control portion is smaller than a width of the first light-emitting control portion.

Optionally, the power compensation pattern includes a first portion, a second portion, and a third portion; the first portion is coupled with the first power line portion and one end of the third portion, respectively; the second portion is respectively coupled with the main body portion and the other end of the third portion; the third portion extends in the third direction; an extension direction of the first portion and an extension direction of the second portion both intersect each of the first direction and the second direction.

Optionally, in a plane parallel to the base substrate and in a direction perpendicular to the first direction, an end of the power compensation pattern coupled with the first power line portion has a first width; the first width gradually increases in a direction close to the first power line portion.

Optionally, the sub-pixel further includes a light-emitting element; the light-emitting element includes an anode pattern; an orthographic projection of the anode pattern onto the base substrate overlaps with an orthographic projection of the power compensation pattern onto the base substrate.

Optionally, the sub-pixel further includes: a light-emitting element, an initialization signal line pattern, a reset signal line pattern, a gate line pattern, and a light-emitting control signal line pattern; at least one part of the initialization signal line pattern, at least one part of the reset signal line pattern, at least one part of the gate line pattern and at least one part of the light-emitting control signal line pattern all extend along the first direction; the sub-pixel further includes:

a first data line pattern and a second data line pattern which are arranged oppositely along the first direction, wherein at least one part of the first data line pattern and at least one part of the second data line pattern extend along the second direction;

a sub-pixel driving circuit including: a first transistor, a second transistor, a third transistor, a fourth transistor, a fifth transistor, a sixth transistor, a seventh transistor, and a storage capacitor;

a gate electrode of the third transistor is coupled with a second electrode of the first transistor; a first electrode of the third transistor is coupled with a second electrode of the fifth transistor; a second electrode of the third transistor is coupled with the first electrode of the first transistor;

a gate electrode of the first transistor is coupled with the gate line pattern;

a gate electrode of the second transistor is coupled with the reset signal line pattern; a first electrode of the second transistor is coupled with the initialization signal line pattern; a second electrode of the second transistor is coupled with a gate electrode of the third transistor;

a gate electrode of the fourth transistor is coupled with the gate line pattern; a first electrode of the fourth transistor is coupled with the first data line pattern or the second data line pattern; a second electrode of the fourth transistor is coupled with the first electrode of the third transistor;

a gate electrode of the fifth transistor is coupled with the light-emitting control signal line pattern; a first electrode of the fifth transistor is coupled with the power signal line pattern;

a gate electrode of the sixth transistor is coupled with the light-emitting control signal line pattern; a first electrode of the sixth transistor is coupled with the second electrode of the third transistor; a second electrode of the sixth transistor is coupled with the light-emitting element;

a gate electrode of the seventh transistor is coupled with the reset signal line pattern in one next adjacent sub-pixel in the second direction; a first electrode of the seventh transistor is coupled with the initialization signal line pattern in the next adjacent sub-pixel in the second direction; a second electrode of the seventh transistor is coupled with the light-emitting element;

a first electrode plate of the storage capacitor is reused as the gate electrode of the third transistor; a second electrode plate of the storage capacitor is coupled with the power signal line pattern.

Based on the foregoing technical solution of the display substrate, according to a second aspect of the present disclosure, a display device is provided and includes the above display substrate.

Based on the foregoing technical solution of the display substrate, according to a third aspect of the present disclosure, a method for manufacturing a display device is provided and includes fabricating sub-pixels arranged in an array on a base substrate. The fabricating sub-pixels includes: fabricating a power signal line pattern; wherein the power signal line pattern includes a first power line portion and a second power line portion; at least one part of the first power line portion extends in a second direction; the second power line portion includes a main body portion, a first end portion and a second end portion; the main body portion and the first power line portion are arranged in a first direction and are spaced apart from each other; the first direction intersects the second direction; the first end portion and the second end portion are disposed opposite to each other along the second direction; the first end portion is respectively coupled with one end of the main body portion and the first power line portion; the second end portion is respectively coupled with the other end of the main body portion and the first power line portion; an aperture is defined between the first power line portion and the second power line portion.

### BRIEF DESCRIPTION OF THE DRAWINGS

The drawings described herein are used to provide a better understanding of the present disclosure and constitute a part of the present disclosure. The exemplary embodiments of the present disclosure and their descriptions are used to illustrate the present disclosure, and do not constitute an improper limitation of the present disclosure. Wherein:

FIG. 1a is a schematic diagram of a layout of sub-pixels in the related art;

FIG. 1b is a schematic diagram of a layout of an active layer shown in FIG. 1;

FIG. 1c is a schematic diagram of a layout of a first gate metal layer shown in FIG. 1;

FIG. 1d is a schematic diagram of a layout of a second gate metal layer shown in FIG. 1;

FIG. 1e is a schematic diagram of a layout of a source-drain metal layer shown in FIG. 1;

FIG. 2 is a circuit diagram of a sub-pixel driving circuit according to an embodiment of the present disclosure;

FIG. 3 is an operation timing diagram of a sub-pixel driving circuit according to an embodiment of the present disclosure;

FIG. 4 is a schematic diagram of a first layout of sub-pixels according to an embodiment of the present disclosure;

FIG. 5 is a schematic diagram of a layout of an active layer and a first gate metal layer shown in FIG. 4;

FIG. 6 is a schematic diagram of a layout of a second gate metal layer shown in FIG. 4;

FIG. 7 is a schematic diagram of a layout of a first source-drain metal layer shown in FIG. 4;

FIG. 8 is a schematic diagram of a layout of a second source-drain metal layer shown in FIG. 4;

FIG. 9 is a schematic diagram of a second layout of sub-pixels according to an embodiment of the present disclosure;

FIG. 10 is a schematic diagram of a second power line portion shown in FIG. 9;

FIG. 11 is a schematic diagram of a layout of a first source-drain metal layer shown in FIG. 9;

FIG. 12 is a schematic diagram of a layout of a first source-drain metal layer and a second source-drain metal layer shown in FIG. 9;

FIG. 13 is a schematic diagram of a third layout of sub-pixels according to an embodiment of the present disclosure;

FIG. 14 is a schematic diagram of a layout of a first source-drain metal layer shown in FIG. 13;

FIG. 15 is a first schematic diagram showing a connection between a power compensation pattern and a second power line portion shown in FIG. 13;

FIG. 16 is a schematic diagram of a first layout of eight sub-pixels;

FIG. 17 is a schematic cross-sectional view along an A1A2 direction shown in FIG. 16;

FIG. 18 is a schematic diagram of a layout of two source-drain metal layers and an anode layer shown in FIG. 16;

FIG. 19 is a schematic diagram of a layout of a second source-drain metal layer and an anode layer shown in FIG. 16;

FIG. 20 is a schematic diagram of a layout of an active layer shown in FIG. 16;

FIG. 21 is a schematic diagram of a layout of a first gate metal layer shown in FIG. 16;

FIG. 22 is a schematic diagram of a layout of a second gate metal layer shown in FIG. 16;

FIG. 23 is a schematic diagram of a layout of a first source-drain metal layer shown in FIG. 16;

FIG. 24 is a schematic diagram of a fourth layout of sub-pixels according to an embodiment of the present disclosure;

FIG. 25 is a schematic diagram of a second power line portion shown in FIG. 24;

FIG. 26 is a schematic diagram of a layout of a first source-drain metal layer shown in FIG. 24;

FIG. 27 is a schematic diagram of a layout of a first source-drain metal layer shown in FIG. 24;

FIG. 28 is a schematic diagram of a layout of a second source-drain metal layer shown in FIG. 24;

FIG. 29 is a schematic diagram of a layout of a first source-drain metal layer and a second source-drain metal layer shown in FIG. 24;

FIG. 30 is a schematic diagram of a fifth layout of sub-pixels according to an embodiment of the present disclosure;

FIG. 31 is a schematic diagram of a layout of a first source-drain metal layer shown in FIG. 30;

FIG. 32 is a second schematic diagram showing a connection between a power compensation pattern and a second power line portion shown in FIG. 30;

FIG. 33 is a schematic diagram of a second layout of eight sub-pixels;

FIG. 34 is a schematic diagram of a sub-pixel driving circuit included in the eight sub-pixels shown in FIG. 33;

FIG. 35 is a schematic diagram of a layout of an active layer shown in FIG. 33;

FIG. 36 is a schematic diagram of a layout of a first source-drain metal layer shown in FIG. 33;

FIG. 37 is a schematic diagram of a layout of a second source-drain metal layer and an anode layer shown in FIG. 33; and

FIG. 38 is a schematic diagram of a layout of a first source-drain metal layer and an anode layer according to an embodiment of the present disclosure.

### DETAILED DESCRIPTION

In order to further illustrate a display substrate and a method for manufacturing the same, and a display device provided in the embodiments of the present disclosure, a detailed description is given hereinafter in conjunction with the accompanying drawings of the specification.

An AMOLED display panel includes: a base substrate, multiple sub-pixel driving circuits arranged on the base substrate, and multiple light-emitting elements arranged on one side of the sub-pixel driving circuits facing away from the base substrate. The light-emitting elements are corresponding to the sub-pixel drive circuits in a one-to-one manner. The sub-pixel driving circuit is configured to drive the corresponding light-emitting element to emit light, thereby realizing display function of the display panel.

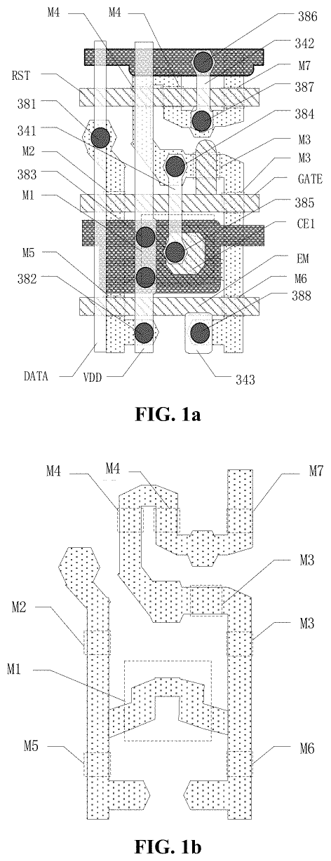

In the related art, the sub-pixel driving circuit generally includes multiple thin film transistors, as shown in FIG. 1a. FIG. 1a shows a specific layout of 7 thin film transistors when the sub-pixel driving circuit includes 7 thin film transistors M1 to M7. With such layout, the sub-pixel driving circuit includes an active layer as shown in FIG. 1b, a first metal layer as shown in FIG. 1c, a second metal layer as shown in FIG. 1d, and a third metal layer as shown in FIG. 1e. The active layer includes an active pattern used to form a channel region of each thin film transistor (e.g., a part within a dashed box in FIG. 1b), and a doped active pattern (e.g., a part outside the dashed box in FIG. 1b) coupled with the active pattern and having conductive properties. The first metal layer includes a gate electrode of each thin film transistor, a scanning signal line GATE coupled with the gate electrode, an electrode plate CE1 of a storage capacitor in the sub-pixel driving circuit, a reset signal line RST, and a light-emitting control signal line EM. The second metal layer includes an initialization signal line VINT, and another electrode plate CE2 of the storage capacitor in the sub-pixel driving circuit. The third metal layer includes a data line DATA, a power signal line VDD, and some conductive connecting portions (e.g., labeled by 341 to 343).

It should be noted that, as shown in FIG. 1, in the layout of the sub-pixel driving circuits, in order to realize the coupling between functional patterns arranged in different layers, some via-holes (e.g., labeled by 381 to 388) may be provided.

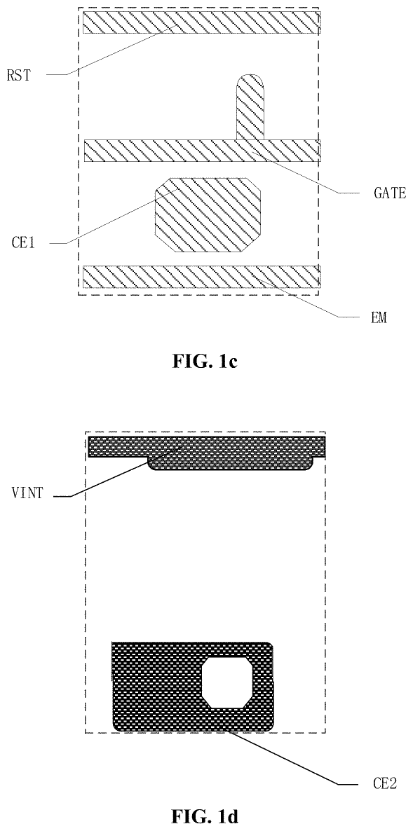

Referring to FIG. 2 to FIG. 4, the present disclosure provides a display substrate, including: a base substrate and an array of sub-pixels arranged on the base substrate. Each sub-pixel includes: a light-emitting element, an initialization signal line pattern 94, a reset signal line pattern 95, a gate line pattern 92, a light-emitting control signal line pattern 93, a power signal line pattern 91, a first data line pattern 981, and a second data line pattern 982 arranged oppositely to the first data line pattern 981 along a first direction.

At least one part of the initialization signal line pattern 94, at least one part of the reset signal line pattern 95, at least one part of the gate line pattern 92, and at least one part of the light-emitting control signal line pattern 93, all extend in the first direction.

At least one part of the power signal line pattern 91, at least one part of the first data line pattern 981, and at least one part of the second data line pattern 982, all extend in a second direction. The first direction intersects the second direction. For example, the first direction includes an X direction, and the second direction includes a Y direction.

All the sub-pixels included in the display substrate may be divided into multiple rows of sub-pixels arranged in sequence along the second direction, and multiple columns of sub-pixels arranged in sequence along the first direction. The initialization signal line patterns 94 included in the sub-pixels located in the same row, are electrically connected in sequence to form an integrated structure. The gate line patterns 92 included in the sub-pixels located in the same row, are electrically connected in sequence to form an integrated structure. The light-emitting control signal line patterns 93 included in the sub-pixels located in the same row, are electrically connected in sequence to form an integrated structure. The reset signal line patterns 95 included in the sub-pixels located in the same row, are electrically connected in sequence to form an integrated structure. The first data line patterns 981 included in the sub-pixels located in the same column, are electrically connected in sequence to form an integrated structure. The second data line patterns 982 included in the sub-pixels located in the same column, are electrically connected in sequence to form an integrated structure. The power signal line patterns 91 included in the sub-pixels located in the same column, are electrically connected in sequence to form an integrated structure.

Each sub-pixel further includes a sub-pixel driving circuit. By taking one sub-pixel driving circuit as an example, the sub-pixel driving circuit includes 7 thin film transistors and 1 capacitor. Each transistor included in the sub-pixel driving circuit adopts a P-type transistor. A first electrode of each transistor is a source electrode. A second electrode of each transistor is a drain electrode.

A first transistor T1 has a dual-gate structure. A gate electrode 201g of the first transistor T1 is coupled with the gate line pattern 92. A source electrode S1 of the first transistor T1 is coupled with a drain electrode D3 of a third transistor T3 (i.e., a driving transistor). A drain electrode D1 of the first transistor T1 is coupled with a gate electrode 203g of the third transistor T3.

A second transistor T2 has a dual-gate structure. A gate electrode 202g of the second transistor T2 is coupled with the reset signal line pattern 95. A source electrode S2 of the second transistor T2 is coupled with the initialization signal line pattern 94. A drain electrode D2 of the second transistor T2 is coupled with the gate electrode 203g of the third transistor T3.

A gate electrode 204g of a fourth transistor T4 is coupled with the gate line pattern 92. A source electrode S4 of the fourth transistor T4 is coupled with the first data line pattern 981 or the second data line pattern 982. A drain electrode D4 of the fourth transistor T4 is coupled with the source electrode S3 of the third transistor T3.

A gate electrode 205g of a fifth transistor T5 is coupled with the light-emitting control signal line pattern 93. A source electrode S5 of the fifth transistor T5 is coupled with the power signal line pattern 91. A drain electrode D5 of the fifth transistor T5 is coupled with the source electrode S3 of the third transistor T3.

A gate electrode 206g of a sixth transistor T6 is coupled with the light-emitting control signal line pattern 93. A source electrode S6 of the sixth transistor T6 is coupled with the drain electrode D3 of the third transistor T3. A drain electrode D6 of the sixth transistor T6 is coupled with an anode of the light-emitting element EL.

A gate electrode 207g of a seventh transistor T7 is coupled with the reset signal line pattern 95′ in the next sub-pixel adjacent in the second direction. A drain electrode D7 of the seventh transistor T7 is coupled with the anode of the corresponding light-emitting element EL. A source electrode S7 of the seventh transistor T7 is coupled with the initialization signal line pattern 94′ in the next sub-pixel adjacent in the second direction.

A first electrode plate Cst1 of a storage capacitor Cst is reused as the gate electrode 203g of the third transistor T3. A second electrode plate Cst2 of the storage capacitor Cst is coupled with the power signal line pattern 91.

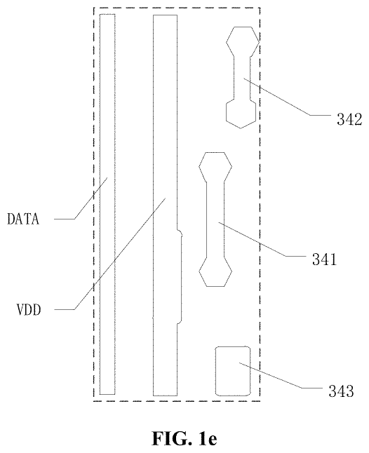

As shown in FIG. 3, when the sub-pixel driving circuit of the above structure is in operation, each operation cycle includes a reset period P1, a write compensation period P2, and a light-emitting period P3. In FIG. 3, E1 represents a light-emitting control signal transmitted on the light-emitting control signal line pattern 93 in the current sub-pixel; R1 represents a reset signal transmitted on the reset signal line pattern 95 in the current sub-pixel; D1 represents a data signal transmitted on a target data line pattern in the current sub-pixel; G1 represents a gate scanning signal transmitted on the gate line pattern 92 in the current sub-pixel; and R1′ represents a reset signal transmitted on the reset signal line pattern 95′ in the next sub-pixel adjacent to the current sub-pixel in the second direction.

In the first reset period P1, the reset signal input by the reset signal line pattern 95 is at an active level, and the second transistor T2 is turned on to input an initialization signal transmitted by the initialization signal line pattern 94 to the gate electrode 203g of the third transistor T3, so that a gate-source voltage Vgs maintained at the third transistor T3 in a previous frame is cleared to zero, thereby resetting the gate electrode 203g of the third transistor T3.

In the write compensation period P2, the reset signal input by the reset signal line pattern 95 is at an inactive level, and the second transistor T2 is turned off, and a gate scanning signal input by the gate line pattern 92 is at an active level to control the first transistor T1 and the fourth transistor T4 to be turned on, data signal is written into the target data line pattern and then is transmitted to the source electrode S3 of the third transistor T3 through the fourth transistor T4. At the same time, the first transistor T1 and the fourth transistor T4 are turned on, so that the third transistor T3 is formed into a diode structure. Therefore, the first transistor T1, the third transistor T3 and the fourth transistor T4 are operated together to compensate a threshold voltage of the third transistor T3. When a compensation time is long enough, a potential of the gate electrode 203g of the third transistor T3 is controlled to finally reach Vdata+Vth, where Vdata represents a voltage value of the data signal, and Vth represents the threshold voltage of the third transistor T3.

In the write compensation period P2, the reset signal input by the reset signal line pattern 95′ is at an active level to control the seventh transistor T7 to be turned on, so that an initialization signal transmitted by the initialization signal line pattern 94′ is input to the anode of the light-emitting element EL to control the light-emitting element EL to not emit light.

In the light-emitting period P3, a light-emitting control signal written in the light-emitting control signal line pattern 93 is at an effective level, to control the fifth transistor T5 and the sixth transistor T6 to be turned on, so that a power signal transmitted by the power signal line pattern 91 is input to the source electrode S3 of the third transistor T3. At the same time, since the potential of the gate electrode 203g of the third transistor T3 is maintained at Vdata+Vth, the third transistor T3 is turned on. A corresponding gate-source voltage of the third transistor T3 is Vdata+Vth−VDD, where VDD is a voltage value corresponding to the power signal. A leakage current generated based on the gate-source voltage flows to the anode of the corresponding light-emitting element EL, and drives the corresponding light-emitting element EL to emit light.

When fabricating the foregoing sub-pixels, a layout of each layer corresponding to the sub-pixels is as follows.

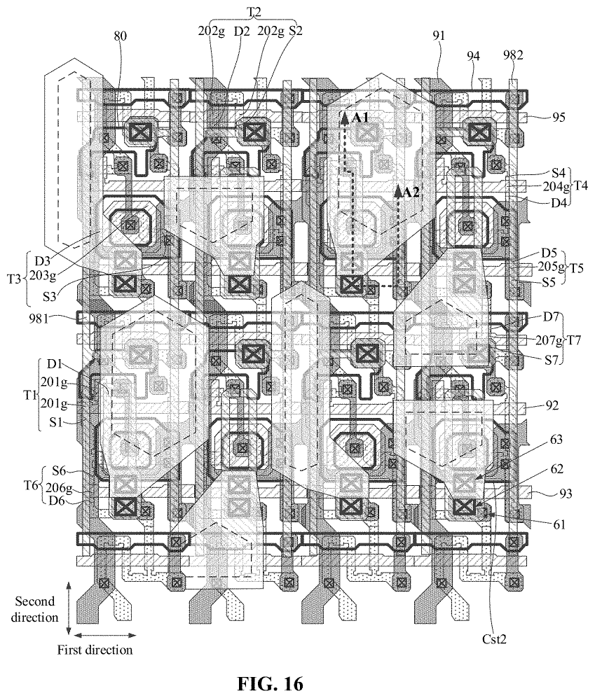

As shown in FIG. 17, an active film layer, a first gate insulation layer GI1, a first gate metal layer, a second gate insulation layer GI2, a second gate metal layer, an interlayer insulation layer ILD, a first source-drain metal layer, a first planarization layer PLN1, a second source-drain metal layer, a second planarization layer PLN2 and an anode layer, are sequentially stacked in a direction away from the base substrate.

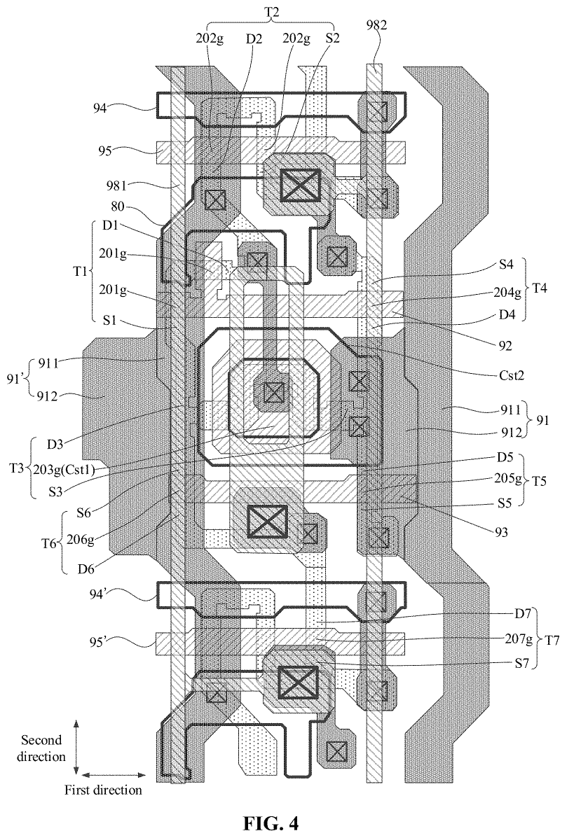

As shown in FIG. 5, the active film layer is used to form a channel region (e.g., a part covered by the gate electrode of each transistor), a source electrode (e.g., S1 to S7) and a drain electrode (e.g., D1 to D7) of each transistor in the sub-pixel driving circuit. Due to the doping effect, a conductivity of portions of the active film layer corresponding to the source electrode and the drain electrode is better than a conductivity of portions of the active film layer corresponding to channel region. The active film layer may be made of amorphous silicon, polysilicon, oxide semiconductor materials, etc. It should be noted that the foregoing source electrode and drain electrode may be doped with n-type impurities or p-type impurities.

As shown in FIG. 5, the first gate metal layer is used to form a gate electrode (e.g., 201g to 207g) of each transistor in the sub-pixel driving circuit, as well as the gate line pattern 92, the light-emitting control signal line pattern 93 and the reset signal line pattern 95 which are included in each sub-pixel driving circuit. The gate electrode 203g of the third transistor T3 in each sub-pixel driving circuit is reused as the first electrode plate Cst1 of the second storage capacitor Cst in the sub-pixel driving circuit.

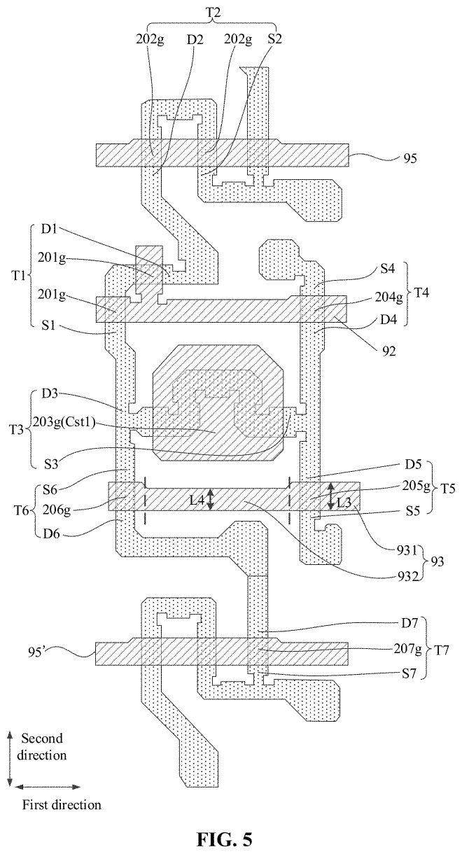

As shown in FIG. 6, the second gate metal layer is used to form the second electrode plate Cst2 of the second storage capacitor Cst, the initialization signal line pattern 94 included in the sub-pixel, and a shield pattern 80.

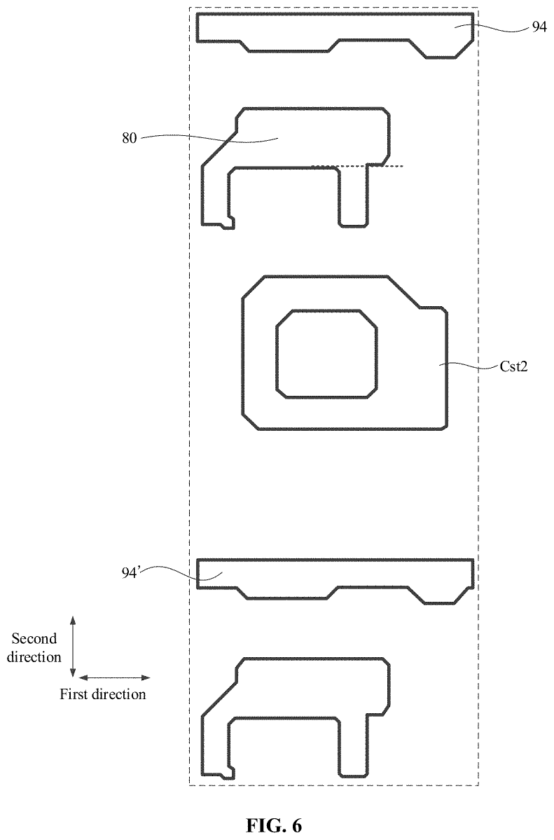

As shown in FIG. 7, the first source-drain metal layer is used to form the power signal line pattern 91 and some conductive connection portions included in the sub-pixel. It should be noted that in order to ensure stability of the power signal transmitted by the power signal line pattern 91, when laying out the power signal line pattern 91, a width of the power signal line pattern 91 in a direction perpendicular to an extension direction of the power signal line pattern 91, is widened as much as possible, under the premise of avoiding conductive connection portions and some via-holes on the same layer.

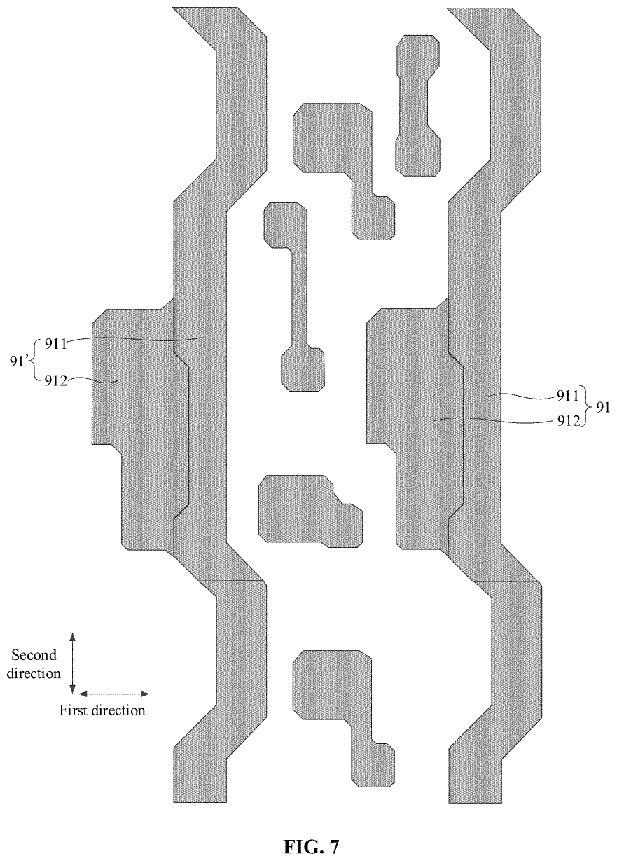

As shown in FIG. 8, the second source-drain metal layer is used to form the first data line pattern 981, the second data line pattern 982 and some conductive connection portions included in the sub-pixel.

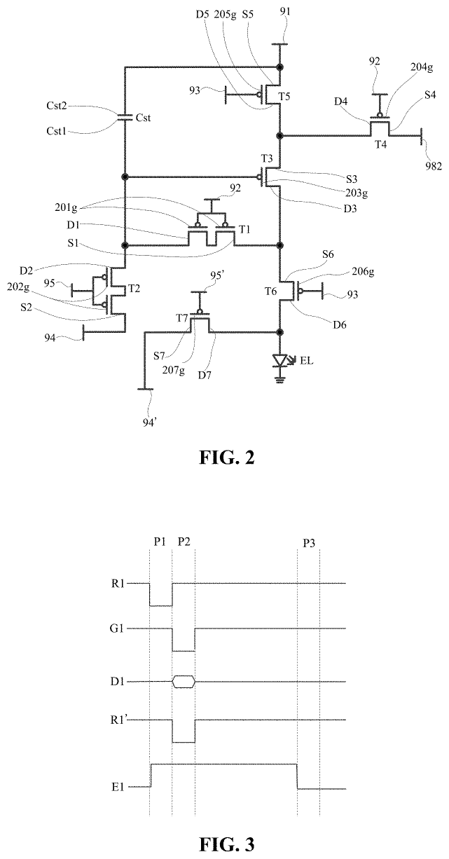

In addition, as shown in FIG. 4, in the display substrate provided in the present disclosure, in the second direction, the gate electrode 204g of the fourth transistor T4, the gate electrode 201g of the first transistor Ti and the gate electrode 202g of the second transistor T2 are all located at a first side of the gate electrode 203g of the third transistor T3; the gate electrode of the seventh transistor T7, the gate electrode 206g of the sixth transistor T6, and the gate electrode of the fifth transistor T5 are all located at a second side of the gate electrode of the driving transistor. For example, the first side and the second side of the gate electrode of the driving transistor are two opposite sides along the second direction. Further, the first side of the gate electrode 203g of the third transistor T3 may be an upper side of the gate electrode 203g of the third transistor T3, and the second side of the gate electrode 203g of the third transistor T3 may be a lower side of the gate electrode 203g of the third transistor T3. As for the lower side, for example, one side of the display substrate for binding an IC is a lower side of the display substrate. The lower side of the gate electrode 203g of the third transistor T3 is, one side of the gate electrode 203g of the third transistor T3, which is closer to the IC. The upper side is an opposite side of the lower side, for example, one side of the gate electrode 203g of the third transistor T3, which is far away from the IC.

In the first direction, the gate electrode 204g of the fourth transistor T4 and the gate electrode 205g of the fifth transistor T5 are both located at a third side of the gate electrode 203g of the third transistor T3; and the gate electrode 201g of the first transistor T1 and the gate electrode 206g of the sixth transistor T6 are both located at a fourth side of the gate electrode 203g of the third transistor T3. For example, the third side and the fourth side of the gate electrode 203g of the third transistor T3 are two opposite sides along the first direction. Further, the third side of the gate electrode 203g of the third transistor T3 may be a right side of the gate electrode 203g of the third transistor T3, and the fourth side of the gate electrode 203g of the third transistor T3 may be a left side of the gate electrode 203g of the third transistor T3. As for the left and right sides, for example, in the same sub-pixel, the second data line pattern 982 is located at the right side of the gate electrode 203g of the third transistor T3, and the first data line pattern 981 is located at the left side of the gate electrode 203g of the third transistor T3.

When the display substrate is compatible with the optical fingerprint recognition technology, due to the principle of the optical fingerprint recognition, this technology has certain requirements on transmittance of the display substrate. That is, a light signal of sufficient intensity is required to enable a light-sensitive sensor (hereinafter referred to as sensor) to respond to light, thereby shortening response time of fingerprint recognition.

When the display substrate with the above structure is used for under-screen fingerprint recognition, since the display substrate covers the sensor, traces and components such as metal conductors and P—Si semiconductors (used to form the active layer) included in each sub-pixel in the display substrate occupy more than 85% of an area of the display substrate, and the occupies areas have a greater shielding effect on electromagnetic waves, which reduce signal-to-noise ratio of optical fingerprint recognition and detection, and limit the fingerprint detection speed.

In order to increase transmittance of the display substrate, a layout of a backplane in the display substrate may be changed. For example, the transmittance may be improved by narrowing widths of metal traces, compressing sizes of light-emitting elements, and compressing sizes of transistors or capacitors. However, although the foregoing solutions can improve the resolution, they are likely to have an adverse impact on performance of the display substrate.

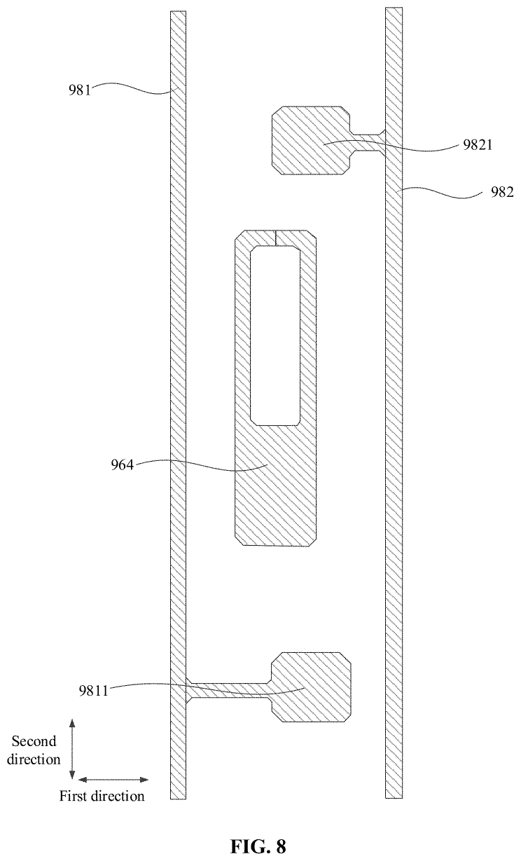

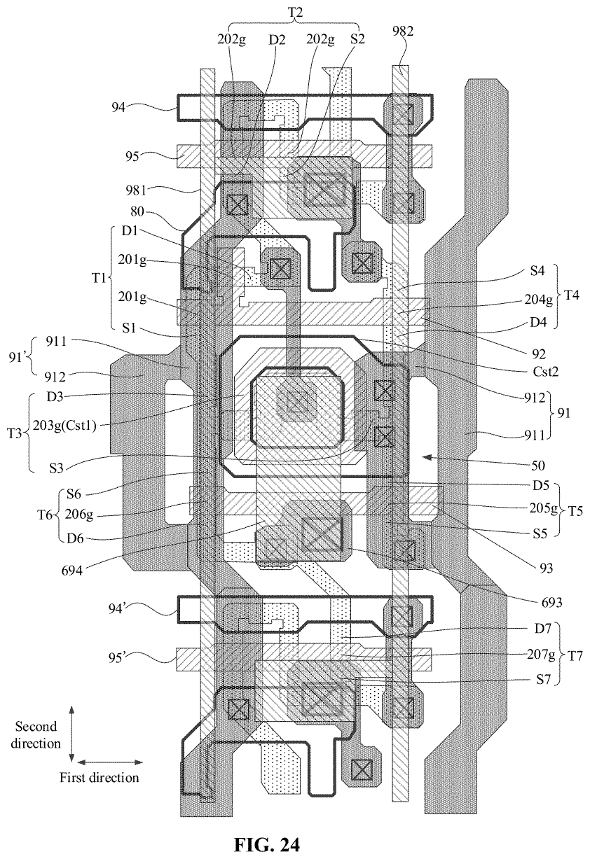

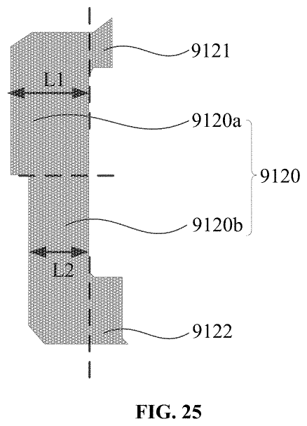

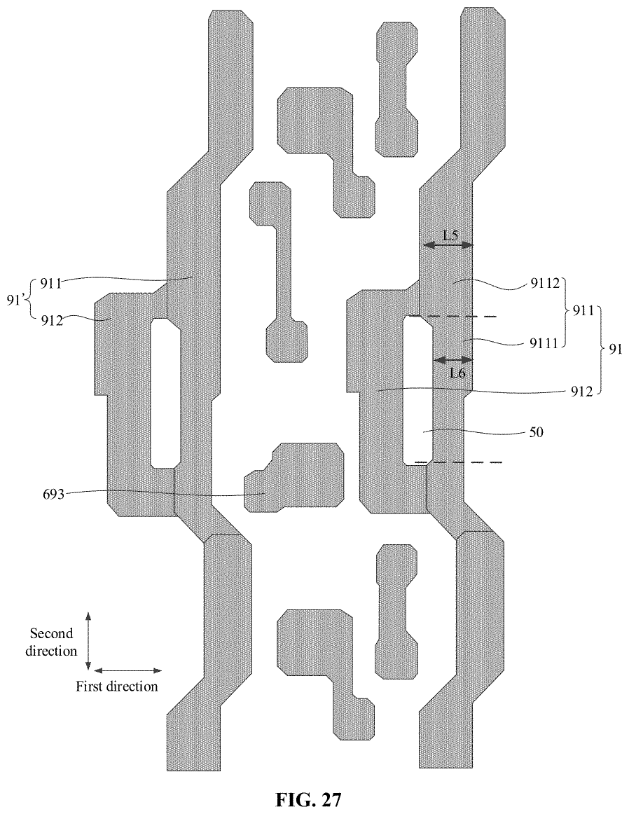

Referring to FIG. 9 to FIG. 11, FIG. 24, FIG. 25 and FIG. 27, one embodiment of the present disclosure provides a display substrate, including: a base substrate and an array of sub-pixels arrayed on the base substrate. The sub-pixels include a power signal line pattern 91.

The power signal line pattern 91 includes a first power line portion 911 and a second power line portion 912. At least one part of the first power line portion 911 extends in a second direction. The second power line portion 912 includes a main body portion 9120, a first end portion 9121, and a second end portion 9122. The main body portion 9120 and the first power line portion 911 are arranged in a first direction and spaced from each other. The first direction intersects the second direction. The first end portion 9121 and the second end portion 9122 are arranged opposite to each other along the second direction. The first end portion 9121 is respectively coupled with one end of the main body portion 9120 and the first power line portion 911. The second end portion 9122 is respectively coupled with the other end of the main body portion 9120 and the first power line portion 911. An aperture 50 is defined between the first power line portion 911 and the second power line portion 912.

Specifically, the display substrate includes multiple sub-pixels arranged in an array on the base substrate. The multiple sub-pixels may be divided into multiple rows of sub-pixels and multiple columns of sub-pixels. The multiple rows of sub-pixels are arranged along the second direction. Each row of sub-pixels includes multiple sub-pixels sequentially arranged along the first direction. The multiple columns of sub-pixels are arranged along the first direction. Each column of sub-pixels includes multiple sub-pixels sequentially arranged along the second direction.

Each sub-pixel includes the power signal line pattern 91. The power signal line pattern 91 includes a first power line portion 911 and a second power line portion 912. At least one part of the first power line portion 911 extends along the second direction. In the same column of sub-pixels, the first power line portions 911 included in various sub-pixels are electrically connected in sequence to form an integral structure.

The second power line portion 912 includes a main body portion 9120, a first end portion 9121, and a second end portion 9122. For example, at least one part of the main body portion 9120 extends along the second direction. For example, in a plane parallel to the base substrate and in a direction perpendicular to the second direction, a thickness of the main body portion 9120 is uniform or non-uniform. For example, the main body portion 9120 and the first power line portion 911 are arranged along the first direction, and the main body portion 9120 and the first power line portion 911 are spaced apart. Along the first direction, a distance between the main body portion 9120 and the first power line portion 911 determines a width of the aperture 50 in the first direction.

For example, the first end portion 9121 and the second end portion 9122 are arranged opposite to each other along the second direction. The first end portion 9121 is respectively coupled with an end of the main body portion 9120 and the first power line portion 911. The second end portion 9122 is respectively coupled with the other end of the main body portion 9120 and the first power line portion 911. The main body portion 9120, the first end portion 9121, the second end portion 9122 and the first power line portion 911 together enclose the aperture 50. In the second direction, a length of the main body portion 9120 and a distance between the first end portion 9121 and the second end portion 9122, determine a length of the aperture 50 in the first direction.

For example, the main body portion 9120, the first end portion 9121, the second end portion 9122 and the first power line portion 911 are formed as an integral structure. It should be noted that the integrated structure includes: the main body portion 9120, the first end portion 9121, the second end portion 9122 and the first power line portion which are in contact with each other and which are simultaneously formed with the same material through a patterning process.

According to the specific structure of the foregoing display substrate, in the display substrate provided in the embodiment of the present disclosure, the power signal line pattern 91 includes the first power line portion 911 and the second power line portion 912, so that the aperture 50 is formed between the first power line portion 911 and the second power line portion 912, thereby reducing a proportion of an opaque area in the display substrate and improving a light transmittance of the display substrate. Therefore, when the display substrate provided in the embodiments of the present disclosure is compatible with the optical fingerprint recognition technology, the display substrate can provide good conditions for the sensor to collect light signals, thereby effectively improving speed and accuracy of fingerprint recognition.

In addition, in the display substrate provided in the embodiment of the present disclosure, the aperture is formed only in the power signal line pattern 91, without performing operations such as narrowing widths of metal traces except for the power signal line pattern 91, compressing sizes of light-emitting elements, and compressing sizes of transistors or capacitors. Therefore, the display substrate provided in the embodiments of the present disclosure improves the resolution without adversely affecting performance of the display substrate.

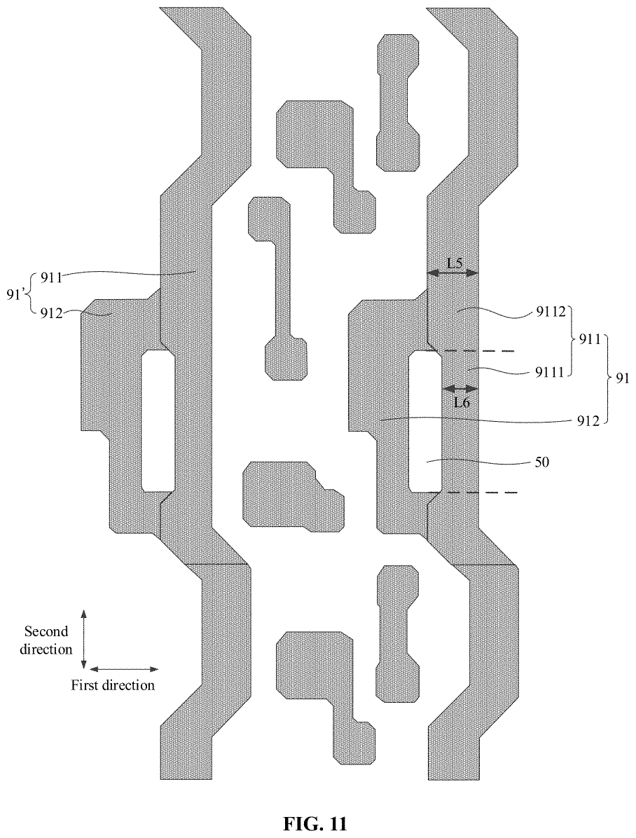

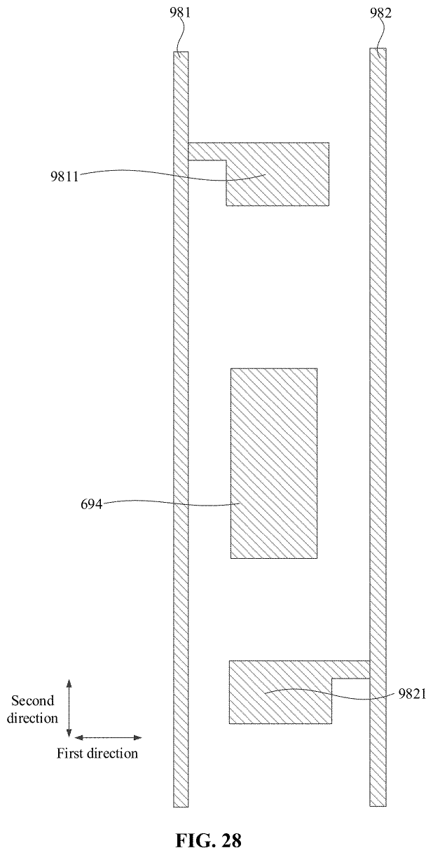

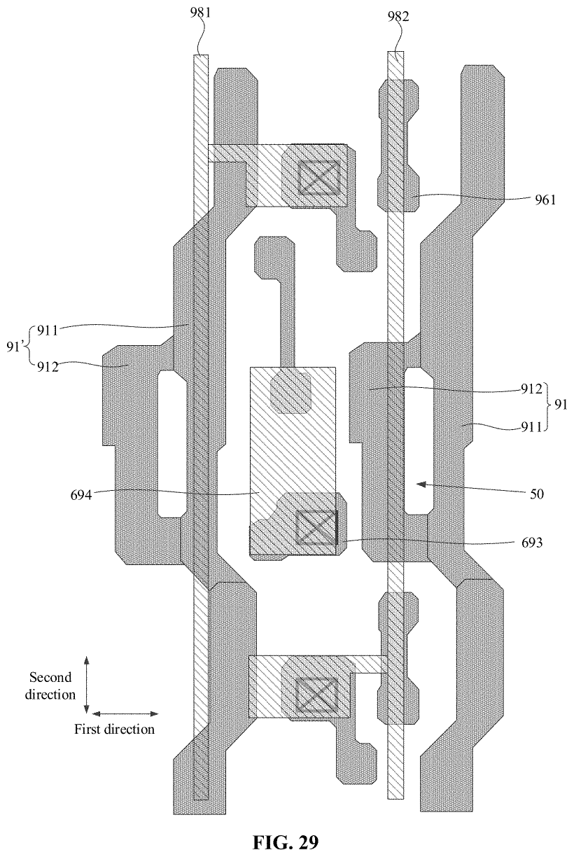

As shown in FIG. 8, FIG. 12, FIG. 28 and FIG. 29, in some embodiments, the multiple sub-pixels are divided into multiple rows of sub-pixels. Each row of sub-pixels includes multiple sub-pixels arranged in sequence along a first direction. The sub-pixel further includes: a first data line pattern 981 and a second data line pattern 982 arranged oppositely along the first direction.

At least one part of the first data line pattern 981 and at least one part of the second data line pattern 982 extend along a second direction. An orthographic projection of the first data line pattern 981 onto the base substrate, overlaps with an orthographic projection of the first power line portion 911 in the sub-pixel which is adjacent, in the first direction, to the sub-pixel that the first data line pattern 981 belongs to, onto the base substrate. An orthographic projection of the second data line pattern 982 onto the base substrate overlaps with an orthographic projection of the main body portion 9120 onto the base substrate.

Specifically, the display substrate includes multiple sub-pixels arranged in an array on a base substrate. The multiple sub-pixels may be divided into multiple rows of sub-pixels and multiple columns of sub-pixels. The multiple rows of sub-pixels are arranged along a second direction. Each row of sub-pixels includes multiple sub-pixels sequentially arranged along a first direction. The multiple columns of sub-pixels are arranged along the first direction. Each column of sub-pixels includes multiple sub-pixels sequentially arranged along the second direction.

For example, the first direction includes a horizontal direction, and the second direction includes a vertical direction.

Each sub-pixel includes a first data line pattern 981 and a second data line pattern 982 arranged opposite to each other along the first direction. At least one part of the first data line pattern 981 and at least one part of the second data line pattern 982 extend in the second direction. The first data line patterns 981 included in various sub-pixels in the same column of sub-pixels are electrically connected in sequence to form an integrated structure. The second data line patterns 982 included in various sub-pixels in the same column of sub-pixels are electrically connected in sequence to form an integrated structure.

As shown in FIG. 8 and FIG. 28, for example, the first data line pattern 981 includes a first protrusion 9811, and the second data line pattern 982 includes a second protrusion 9812. The first protrusion 9811 and the second protrusion 9812 are used for electrical connection with the first electrode S4 of the fourth transistor T4.

For example, in the same column of sub-pixels, an odd-numbered sub-pixel receives data signal provided by the first data line pattern 981 included therein, and an even-numbered sub-pixel receives data signal provided by the second data line pattern 982 included therein.

For example, in the same column of sub-pixels, an even-numbered sub-pixel receives data signal provided by the first data line pattern 981 included therein, and an odd-numbered sub-pixel receives data signal provided by the second data line pattern 982 included therein.

Each sub-pixel includes a sub-pixel driving circuit. The sub-pixel driving circuit includes a storage capacitor and multiple thin film transistors. As shown in FIG. 2, FIG. 9 and FIG. 24, for example, the sub-pixel driving circuit includes 7T1C, that is, 7 transistors and a storage capacitor. The sub-pixel driving circuit is configured to generate a driving signal for driving the light-emitting element to emit light.

For example, the sub-pixel driving circuit includes a driving transistor (i.e., a third transistor) and a data writing transistor (i.e., a fourth transistor T4). A first electrode of the data writing transistor is coupled with the first data line pattern 981 or the second data line pattern 982 to receive data signal provided by the first data line pattern 981 or the second data line pattern 982. A second electrode of the data writing transistor is coupled with a first electrode of the driving transistor. The data writing transistor can transmit the data signal received by the first electrode thereof to the first electrode of the driving transistor.

In the same column of sub-pixels, the first electrodes of the data writing transistors in adjacent sub-pixels are coupled with different data line patterns. Specifically, in the same column of sub-pixels, the first electrode of the data writing transistor included in one of adjacent sub-pixels is coupled with the first data line pattern 981, and the first electrode of the data writing transistor included in the other of adjacent sub-pixels is coupled with the second data line pattern 982.

In the display substrate provided in the foregoing embodiment, each sub-pixel includes the first data line pattern 981 and the second data line pattern 982, and in the same column of sub-pixels, the data writing transistors in adjacent sub-pixels are coupled with different data line patterns, so that in the same column of sub-pixels, adjacent sub-pixels are provided with data signals from different data line patterns, which ensures that each sub-pixel has enough data signal writing time, thereby solving the problem of insufficient data signal writing time of each row of sub-pixels when the display substrate is displayed at high frequency.

Specific layout positions of the apertures 50 are various. For example, as shown in FIG. 12, an orthographic projection of the first data line pattern 981 onto the base substrate, overlaps with an orthographic projection of the first power line portion 911 (i.e., the first power line portion 911 included in the power signal line pattern 91′) in a previous sub-pixel which is adjacent, in the first direction, to the sub-pixel that the first data line pattern 981 belongs to, onto the base substrate. An orthographic projection of the second data line pattern 982 onto the base substrate overlaps with an orthographic projection of the main body portion 9120 onto the base substrate. In this layout, the aperture 50 is located near the second data line pattern 982 in the sub-pixel to which the aperture 50 belongs, and near the first data line pattern 981 in the next sub-pixel which is adjacent, in the first direction, to the sub-pixel to which the aperture 50 belongs.

In the foregoing layout, an overlap area between the orthographic projection of the first data line pattern 981 onto the base substrate and an orthographic projection of a functional pattern with a fixed potential onto the base substrate, is close to, an overlap area between the orthographic projection of the second data line pattern 982 onto the base substrate and the orthographic projection of the functional pattern with a fixed potential onto the base substrate, thereby effectively reducing load difference between the first data line pattern 981 and the second data line pattern 981.

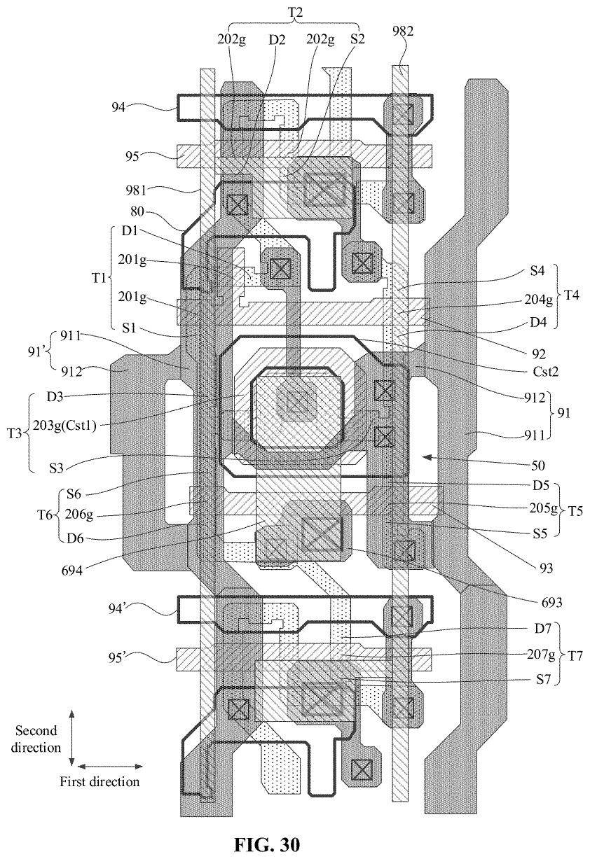

It should be noted that, as shown in FIG. 9, FIG. 12, FIG. 29 and FIG. 30, the functional pattern with a fixed potential includes: a power signal line pattern 91, an initialization signal line pattern 94, and a conductive functional pattern 961 coupled with the power signal line pattern 91 or the initialization signal line pattern 94.

As shown in FIG. 8, FIG. 12, FIG. 28 and FIG. 29, in some embodiments, the orthographic projection of the first data line pattern 981 onto the base substrate does not overlap with an orthographic projection of the aperture 50 onto the base substrate; and/or, the orthographic projection of the second data line pattern 982 onto the base substrate does not overlap with an orthographic projection of the aperture 50 onto the base substrate.

By setting the orthographic projection of the first data line pattern 981 onto the base substrate not overlapping the orthographic projection of the aperture 50 onto the base substrate, it avoids the first data line pattern 981 from shielding the aperture 50, thereby better ensuring light transmittance of the aperture 50.

Similarly, by setting the orthographic projection of the second data line pattern 982 onto the base substrate not overlapping the orthographic projection of the aperture 50 onto the base substrate, it avoids the second data line pattern 982 from shielding the aperture 50, thereby better ensuring light transmittance of the aperture 50.

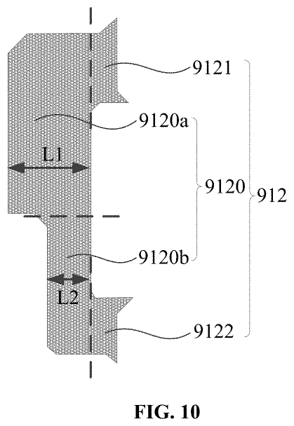

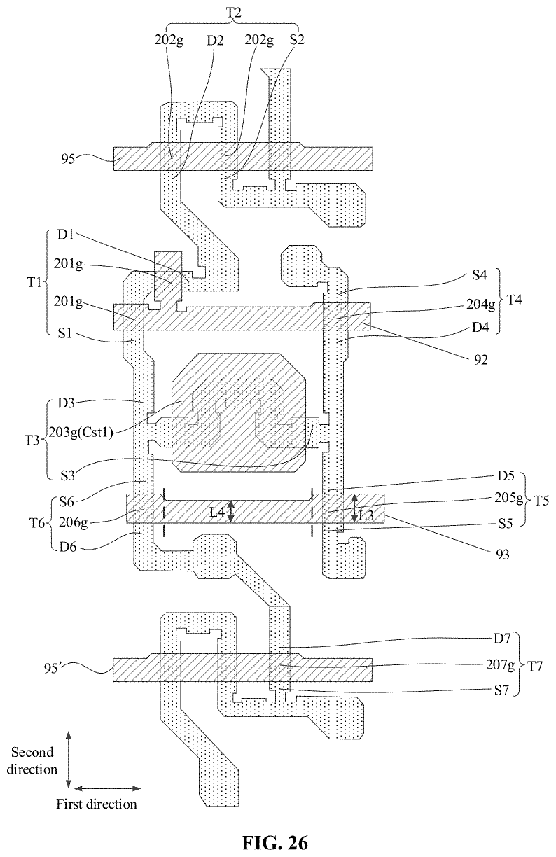

As shown in FIG. 5, FIG. 9, FIG. 11, FIG. 24, FIG. 26 and FIG. 27, in some embodiments, the sub-pixel further includes a light-emitting control signal line pattern 93. At least one part of the light-emitting control signal line pattern 93 extends along the first direction. An orthographic projection of the light-emitting control signal line pattern 93 onto the base substrate partially overlaps with the orthographic projection of the aperture 50 onto the base substrate.

Specifically, the sub-pixel further includes a light-emitting control signal line pattern 93. The light-emitting control signal line pattern 93 is configured to transmit light-emitting control signals. At least one part of the light-emitting control signal line pattern 93 extends along the first direction. The light-emitting control signal line patterns 93 included in various sub-pixels located in the same row along the first direction are electrically connected in sequence to form an integral structure.

By setting the orthographic projection of the light-emitting control signal line pattern 93 onto the base substrate partially overlapping the orthographic projection of the aperture 50 onto the base substrate, it reduces an overlap area between the light-emitting control signal line pattern 93 and the power signal line pattern 91 with a fixed potential, thereby effectively reducing loads of the light-emitting control signal line pattern 93 and power consumption caused by the loads.

As shown in FIG. 11 and FIG. 27, in some embodiments, the first power line portion 911 includes a second sub-portion 9112 and a first sub-portion 9111 for enclosing the aperture 50. In a plane parallel to the base substrate in a direction perpendicular to the second direction, a width L6 of the first sub-portion 9111 is less than a width L5 of the second sub-portion 9112.

Specifically, the first power line portion 911 includes a first sub-portion 9111 for enclosing the aperture 50 and a second sub-portion 9112 which is other part that is not used to enclose the aperture 50. For example, the first sub-portion 9111 and the second sub-portion 9112 are formed as an integral structure. For example, the second power line portion 912 is directly coupled with the second sub-portion 9112.

In a plane parallel to the base substrate in a direction perpendicular to the second direction, the width L6 of the first sub-portion 9111 is less than the width L5 of the second sub-portion 9112, so that in the first direction, a distance between the main body portion 9120 and the first power line portion 911 becomes larger, thereby increasing the width of the aperture 50 in the first direction and further improving the transmittance of the display substrate.

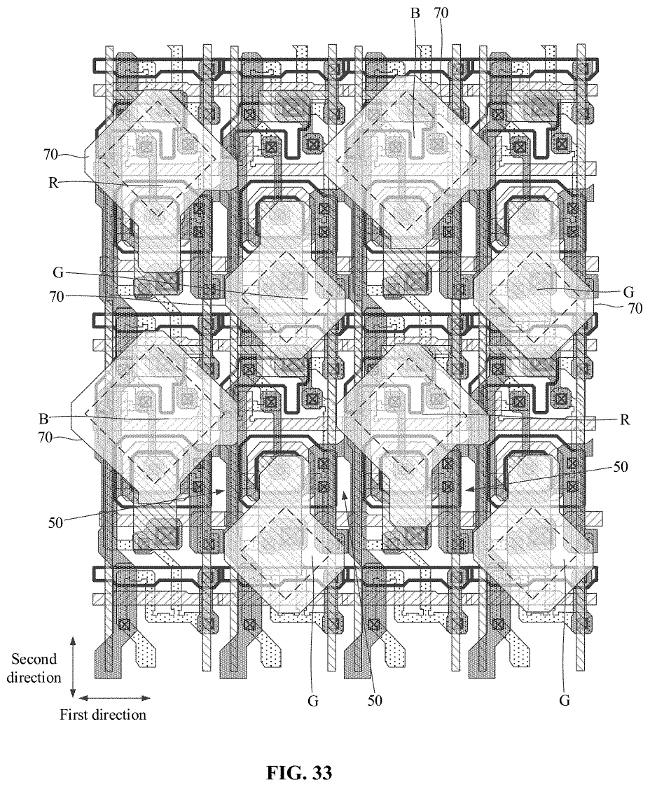

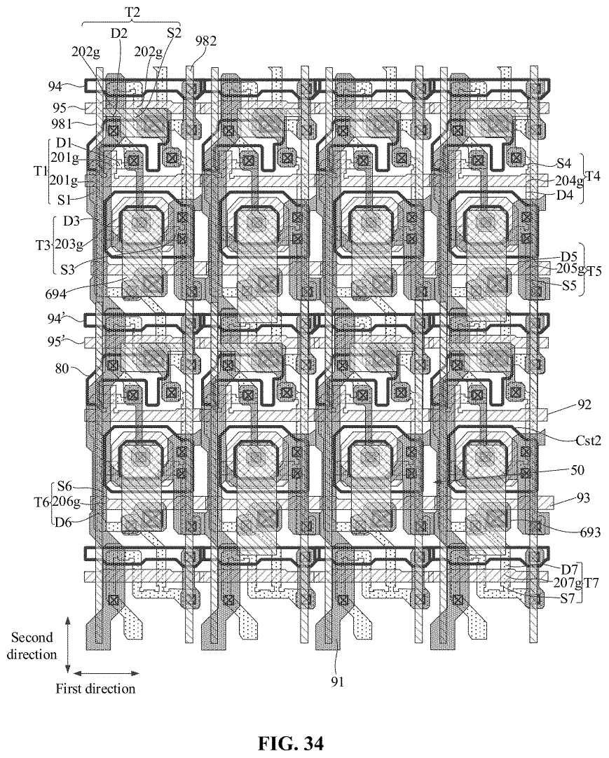

As shown in FIG. 33 and FIG. 34, in some embodiments, the sub-pixel further includes a light-emitting element. The light-emitting element includes an anode pattern 70. An orthographic projection of the anode pattern 70 onto the base substrate does not overlap with the orthographic projection of the aperture 50 onto the base substrate.

Specifically, the light-emitting element includes an anode pattern 70, a light-emitting function layer and a cathode that are sequentially stacked in a direction away from the base substrate. The anode pattern 70 is coupled with the sub-pixel driving circuit in the sub-pixel to which the anode pattern 70 belongs, and receives a driving signal provided by the sub-pixel driving circuit. The light-emitting function layer includes common layers of entire layers, such as an organic light-emitting material layer. In addition, the light-emitting function layer may further include: an electron transporting layer (ETL for short), an electron injection layer (EIL for short), a hole transporting layer (HTL for short) and a hole injection layer (HIL for short). The cathode is coupled with a negative power signal line VSS in the display substrate, and receives a negative power signal provided by the negative power signal line VSS. The light-emitting function layer emits light under action of the anode pattern 70 and the cathode, thereby realize the display function of the display substrate.

By setting the orthographic projection of the anode pattern 70 onto the base substrate not overlapping the orthographic projection of the aperture 50 onto the base substrate, it avoids the anode pattern 70 from shielding the aperture 50, thereby better ensuring light transmittance of the aperture 50.

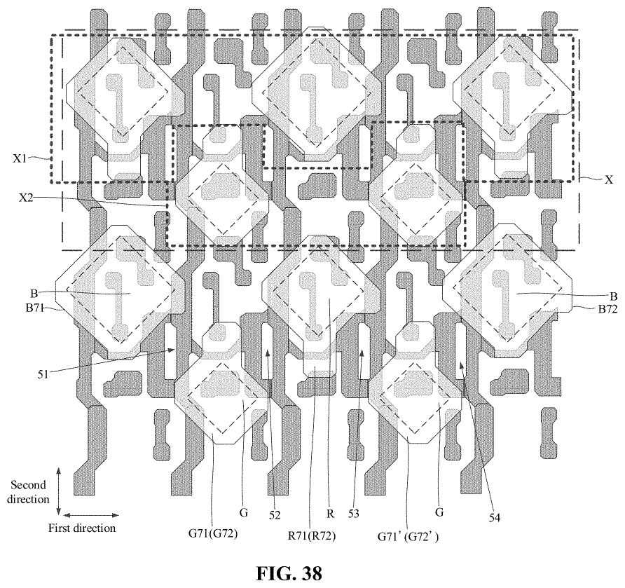

As shown in FIG. 33, FIG. 34 and FIG. 38, in some embodiments, the orthographic projection of the aperture 50 onto the base substrate is between an orthographic projection of a first anode pattern onto the base substrate and an orthographic projection of a second anode pattern onto the base substrate. The sub-pixel to which the aperture 50 belongs, includes the first anode pattern, and a next sub-pixel adjacent to the sub-pixel in the first direction includes the second anode pattern.

Specifically, each sub-pixel includes a sub-pixel driving circuit and a light-emitting element located at one side of the sub-pixel driving circuit away from the base substrate. For example, a structure of the sub-pixel driving circuit is shown in FIG. 2. An anode pattern included in the light-emitting element is coupled with a drain electrode D6 of a sixth transistor T6 in the sub-pixel driving circuit to receive a driving signal output from the drain electrode D6 of the sixth transistor T6.

A layout relationship between the aperture 50 and the anode pattern 70 is various. For example, the orthographic projection of the aperture 50 onto the base substrate, is between the orthographic projection of the first anode pattern onto the base substrate and the orthographic projection of the second anode pattern onto the base substrate. The first anode pattern is the anode pattern 70 included in the sub-pixel to which the aperture 50 belongs, and the second anode pattern is the anode pattern 70 included in the next sub-pixel which is adjacent, in the first direction, to the sub-pixel to which the aperture 50 belongs.

For example, the first anode pattern and the second anode pattern are arranged along a third direction. The third direction intersects both the first direction and the second direction. For example, the third direction may be 45 degrees relative to the first direction. For example, the third direction may be 135 degrees relative to the first direction.

For example, the orthographic projection of the aperture 50 onto the base substrate does not overlap with the orthographic projection of the first anode pattern onto the base substrate, and the orthographic projection of the aperture 50 onto the base substrate does not overlap with the orthographic projection of the second anode pattern onto the base substrate.

By setting the orthographic projection of the aperture 50 onto the base substrate between the orthographic projection of the first anode pattern onto the base substrate and the orthographic projection of the second anode pattern onto the base substrate, a layout space on the display substrate can be better utilized to maximize the size of the aperture 50 while ensuring that the aperture 50 will not be shielded by the first anode pattern and the second anode pattern.

As shown in FIG. 33 and FIG. 34, in some embodiments, the multiple sub-pixels are divided into multiple pixel units. Each pixel unit includes a red sub-pixel R, a blue sub-pixel B, and two green sub-pixels G.

As shown in FIG. 38, in the pixel units (e.g., labeled by X) in the same row along the first direction, an anode pattern (e.g., R71/R72) included in the red sub-pixel R in each pixel unit and an anode pattern (e.g., B71/B72) included in the blue sub-pixel B in each pixel unit are distributed in one row (e.g., labeled by X1); and an anode pattern (e.g., G71/G72/G71′/G72′) included in the green sub-pixel Gin each pixel unit are distributed in another row (e.g., labeled by X2).

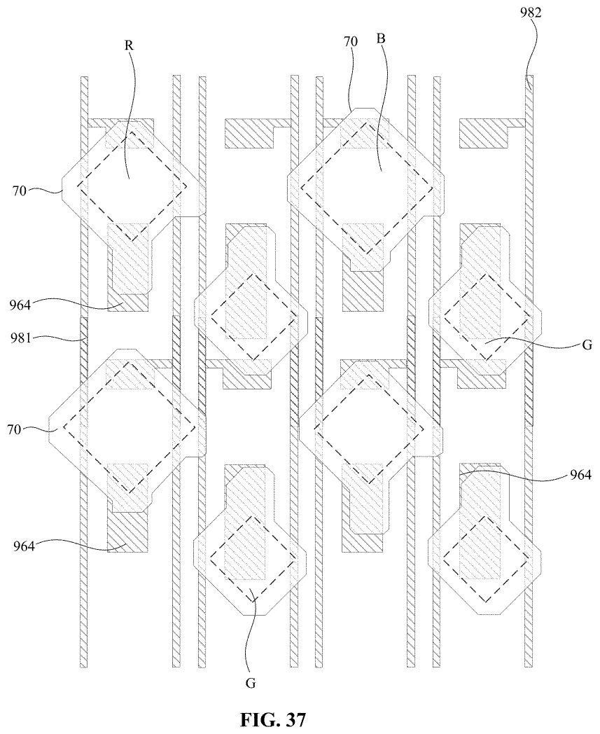

As shown in FIG. 33 and FIG. 37, in the pixel units located in the same row along the first direction, an anode pattern 70 included in the red sub-pixel R, an anode pattern 70 included in the blue sub-pixel B and an anode pattern 70 included in the green sub-pixel G are alternately distributed in sequence.

In the pixel units located in the same row along the first direction, one of adjacent red sub-pixel R and green sub-pixel G includes the first anode pattern, and the other of adjacent red sub-pixel R and green sub-pixel G includes the second anode pattern.

In the pixel units located in the same row along the first direction, one of adjacent blue sub-pixel B and green sub-pixel G includes the first anode pattern, and the other of adjacent blue sub-pixel B and green sub-pixel G includes the second anode pattern.

Specifically, the multiple sub-pixels are divided into multiple pixel units. The multiple pixel units are arranged in an array. Each pixel unit includes one red sub-pixel R, one blue sub-pixel B, and two green sub-pixels G.

As shown in FIG. 38, for example, in the pixel units located in the same row along the first direction, an anode pattern (e.g., R71/R72) included in the red sub-pixel R in each pixel unit and an anode pattern (e.g., B71/B72) included in the blue sub-pixel B in each pixel unit are distributed in one row; and an anode pattern (e.g., G71/G72/G71′/G72′) included in the green sub-pixel G in each pixel unit are distributed in another row. That is, in the pixel units located in the same row along the first direction, the anode pattern (e.g., G71/G72/G71′/G72′) included in the green sub-pixel G is staggered with the anode pattern (e.g., R71/R72) included in the red sub-pixel R along the second direction. In the pixel units located in the same row along the first direction, the anode pattern (e.g., G71/G72/G71′/G72′) included in the green sub-pixel G is staggered with the anode pattern 70 (e.g., B71/B72) included in the blue sub-pixel B.

As shown in FIG. 33, for example, in the pixel units located in the same row along the first direction, an anode pattern 70 included in the red sub-pixel R, an anode pattern 70 included in the blue sub-pixel B and an anode pattern 70 included in the green sub-pixel G are alternately distributed in sequence. That is, in the pixel units located in the same row along the first direction, all the included sub-pixels are arranged in a manner of RGBGRGBG; or in the pixel units located in the same row along the first direction, all the included sub-pixels are arranged in a manner of BGRGBGRG.

When the display substrate adopts the pixel units of the above structure, for example, in the pixel units located in the same row along the first direction, one of the adjacent red sub-pixel R and green sub-pixel G includes the first anode pattern, and the other of the adjacent red sub-pixel R and green sub-pixel G includes the second anode pattern. Specifically, as shown in FIG. 38, FIG. 38 shows that an orthographic projection of a third aperture 53 onto the base substrate is between an orthographic projection of the first anode pattern R71 included in the red sub-pixel R onto the base substrate and an orthographic projection of the second anode pattern G72′ included in the green sub-pixel G onto the base substrate. FIG. 38 shows that an orthographic projection of a second aperture 52 onto the base substrate is between an orthographic projection of the first anode pattern G71 included in the green sub-pixel G onto the base substrate and an orthographic projection of the second anode pattern R72 included in the red sub-pixel R onto the base substrate.

When the display substrate adopts the pixel units of the above structure, for example, in the pixel units located in the same row along the first direction, one of adjacent blue sub-pixel B and green sub-pixel G includes the first anode pattern, and the other of adjacent blue sub-pixel B and green sub-pixel G includes the second anode pattern. Specifically, as shown in FIG. 38, FIG. 38 shows that an orthographic projection of a fourth aperture 54 onto the base substrate is between an orthographic projection of the first anode pattern G71′ included in the green sub-pixel G onto the base substrate and an orthographic projection of the second anode pattern B72 included in the blue sub-pixel B onto the base substrate. FIG. 38 shows that an orthographic projection of a first aperture 51 onto the base substrate is between an orthographic projection of the first anode pattern B71 included in the blue sub-pixel B onto the base substrate and an orthographic projection of the second anode pattern G72 included in the green sub-pixel G onto the base substrate.

By setting the orthographic projection of the aperture 50 onto the base substrate between the orthographic projection of the first anode pattern onto the base substrate and the orthographic projection of the second anode pattern onto the base substrate, a layout space on the display substrate can be better utilized to maximize the size of the aperture 50 while ensuring that the aperture 50 will not be shielded by the first anode pattern and the second anode pattern.

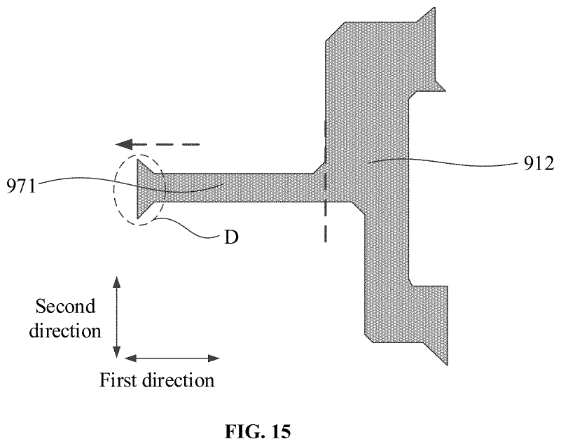

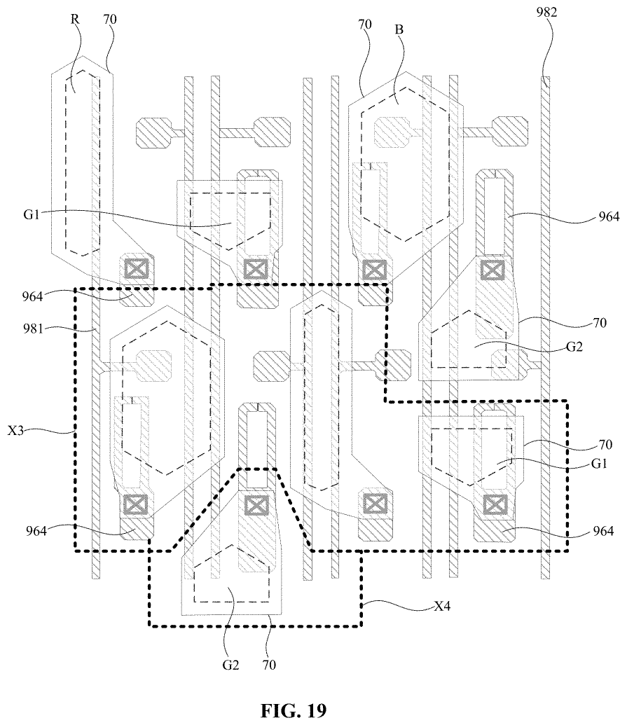

As shown in FIG. 16 to FIG. 19, in some embodiments, the sub-pixel further includes a light-emitting element. The light-emitting element includes an anode pattern 70. An orthographic projection of one anode pattern 70 onto the base substrate overlaps with the orthographic projection of the aperture 50 onto the base substrate.

Specifically, in an actual layout of sub-pixels, due to limitations of the layout space, the orthographic projection of some anode patterns 70 in the display substrate onto the base substrate may partially overlap with the orthographic projection of the aperture 50 onto the base substrate.

For example, the anode pattern 70 may be made of a transparent conductive material, so that even if the orthographic projection of the anode pattern 70 onto the base substrate overlaps with the orthographic projection of the aperture 50 onto the base substrate, a portion of the aperture 50, which is covered by the anode pattern 70, has a certain light transmittance.

It should be noted that the reference number 40 in FIG. 17 represents a base substrate and some film layers (such as a buffer layer, an isolation layer) on the base substrate.

As shown in FIG. 16 to FIG. 19, in some embodiments, the multiple sub-pixels are divided into multiple pixel units. Each pixel unit includes a red sub-pixel R, a blue sub-pixel B, a first green sub-pixel G1 and a second green sub-pixel G2.

Among the pixel units located in the same row along the first direction, in each pixel unit, the anode pattern 70 included in the red sub-pixel R, the anode pattern 70 included in the blue sub-pixel B and the anode pattern 70 included in the first green sub-pixel G1 are distributed in one row (e.g., labeled by X3); in each pixel unit, the anode pattern 70 included in the second green sub-pixel G2 are distributed in another row (e.g., labeled by X4).

The aperture 50 includes a first aperture 501. A part of an orthographic projection of the first aperture 501 onto the base substrate is located within an orthographic projection of the anode pattern 70 included in the first green sub-pixel G1 onto the base substrate.

The other part of the orthographic projection of the first aperture 501 onto the base substrate is located between an orthographic projection of the anode pattern 70 included in the red sub-pixel R onto the base substrate and the orthographic projection of the anode pattern 70 included in the first green sub-pixel G1 onto the base substrate. The anode pattern 70 included in the red sub-pixel R and the anode pattern 70 included in the first green sub-pixel G1 are in the same row.

The other part of the orthographic projection of the first aperture 501 onto the base substrate is located between an orthographic projection of the anode pattern 70 included in the blue sub-pixel B onto the base substrate and the orthographic projection of the anode pattern 70 included in the first green sub-pixel G1 onto the base substrate. The anode pattern included in the blue sub-pixel B and the anode pattern included in the first green sub-pixel G1 are in two adjacent rows.

Specifically, the multiple sub-pixels are divided into multiple pixel units. Each pixel unit includes a red sub-pixel R, a blue sub-pixel B, a first green sub-pixel G1, and a second green sub-pixel G2. For example, in one pixel unit, sub-pixel driving circuits included in sub-pixels of various colors are located in the same row along the first direction.

For example, in the pixel units located in the same row along the first direction, in each pixel unit, the anode pattern 70 included in the red sub-pixel R, the anode pattern 70 included in the blue sub-pixel B, and the anode pattern 70 included in the first green sub-pixel G1 are distributed in one row.

The aperture 50 includes a first aperture 501. For example, one part of an orthographic projection of the first aperture 501 onto the base substrate is located within an orthographic projection of the anode pattern 70 included in the first green sub-pixel G1 onto the base substrate. The other part of the orthographic projection of the first aperture 501 onto the base substrate does not overlap with the orthographic projection of the anode pattern 70 included in the first green sub-pixel G1 onto the base substrate. For example, a proportion of the one part is less than ½ of the entire first aperture 501. For example, the proportion of the one part is approximately ⅓ of the entire first aperture 501.

For example, the other part of the orthographic projection of the first aperture 501 onto the base substrate is located between the orthographic projection of the anode pattern 70 included in the red sub-pixel R onto the base substrate and the orthographic projection of the anode pattern 70 included in the first green sub-pixel G1 onto the base substrate. The anode pattern 70 of the first green sub-pixel G1 may cover a part of the first aperture 501. For example, the anode pattern 70 included in the red sub-pixel R and the anode pattern included in the first green sub-pixel G1 are located in the same row along the first direction. For example, the first aperture 501 belongs to the red sub-pixel R.

The other part of the orthographic projection of the first aperture 501 onto the base substrate is also located between the orthographic projection of the anode pattern 70 included in the blue sub-pixel B onto the base substrate and the orthographic projection of the anode pattern 70 included in the first green sub-pixel G1 onto the base substrate. For example, the anode pattern 70 included in the blue sub-pixel B is located in the next row adjacent to the anode pattern 70 included in the first green sub-pixel G1. For example, the anode pattern 70 included in the blue sub-pixel B and the anode pattern 70 included in the first green sub-pixel G1 are arranged along a fourth direction. The fourth direction intersects the first direction and the second direction.

In some embodiments, an area of a part of the orthographic projection of the first aperture 501 onto the base substrate is less than 50% of an entire area of the orthographic projection of the first aperture 501 onto the base substrate.

As shown in FIG. 16 to FIG. 19, in some embodiments, the multiple sub-pixels are divided into multiple pixel units. Each pixel unit includes a red sub-pixel R, a blue sub-pixel B, a first green sub-pixel G1 and a second green sub-pixel G2.

Among the pixel units located in the same row along the first direction, in each pixel unit, the anode pattern 70 included in the red sub-pixel R, the anode pattern 70 included in the blue sub-pixel B, and the anode pattern 70 included in the first green sub-pixel G1 are distributed in one row (e.g., labeled by X3), and the anode patterns 70 included in the second green sub-pixel G2 in each pixel unit are distributed in another row (e.g., labeled by X4).

The aperture include a second aperture 502. An orthographic projection of the second aperture 502 onto the base substrate is located between the orthographic projection of the anode pattern 70 included in the first green sub-pixel G1 onto the base substrate and the orthographic projection of the anode pattern 70 included in the blue green sub-pixel B onto the base substrate. The orthographic projection of the second aperture 502 onto the base substrate does not overlap with the orthographic projection of the anode pattern 70 included in the red green sub-pixel R onto the base substrate. The anode pattern included in the first green sub-pixel G1 and the anode pattern included in the blue sub-pixel B are located in the same row. The anode pattern included in the red sub-pixel R and the anode patterns included in the first green sub-pixel G1 are located in two adjacent rows.

Specifically, the aperture 50 includes a second aperture 502. For example, an orthographic projection of the second aperture 502 onto the base substrate is located between the orthographic projection of the anode pattern 70 included in the first green sub-pixel G1 onto the base substrate and the orthographic projection of the anode pattern 70 included in the blue green sub-pixel B onto the base substrate. For example, the second aperture 502 belongs to the first green sub-pixel G1. For example, the anode pattern included in the first green sub-pixel G1 and the anode pattern included in the blue sub-pixel B are located in the same row along the first direction.

For example, the orthographic projection of the second aperture 502 onto the base substrate does not overlap with the orthographic projection of the anode pattern 70 included in the first green sub-pixel G1 onto the base substrate. The orthographic projection of the second aperture 502 onto the base substrate does not overlap with the orthographic projection of the anode pattern 70 included in the blue sub-pixel B onto the base substrate. The orthographic projection of the second aperture 502 onto the base substrate does not overlap with the orthographic projection of the anode pattern 70 included in the red sub-pixel R onto the base substrate. For example, the anode pattern included in the red sub-pixel R is located in the next row adjacent to the anode pattern included in the first green sub-pixel G1, and the anode pattern included in the red sub-pixel R is staggered with the anode pattern included in the first green sub-pixel G1 along the second direction, and the anode pattern 70 included in the red sub-pixel R is staggered with the anode pattern 70 included in the blue sub-pixel B along the second direction. For example, the anode pattern 70 included in the red sub-pixel R is staggered with the anode pattern 70 included in the blue sub-pixel B along the second direction

As shown in FIG. 16 to FIG. 19, in some embodiments, the multiple sub-pixels are divided into multiple pixel units. Each pixel unit includes a red sub-pixel R, a blue sub-pixel B, a first green sub-pixel G1 and a second green sub-pixel G2.

Among the pixel units located in the same row along the first direction, in each pixel unit, the anode pattern 70 included in the red sub-pixel R, the anode pattern 70 included in the blue sub-pixel B and the anode pattern 70 included in the first green sub-pixel G1 are distributed in one row (e.g., labeled by X3); and the anode patterns 70 included in the second green sub-pixel G2 in each pixel unit are distributed in another row (e.g., labeled by X4).

The aperture include a third aperture 503. A part of an orthographic projection of the third aperture 503 onto the base substrate is located within an orthographic projection of the anode pattern included in the blue sub-pixel B onto the base substrate.

The other part of the orthographic projection of the third aperture 503 onto the base substrate is located between the orthographic projection of the anode pattern included in the blue sub-pixel B onto the base substrate and the orthographic projection of the anode pattern 70 included in second green sub-pixel G2 onto the base substrate. The anode pattern included in the blue sub-pixel B and the anode pattern included in the second green sub-pixel G2 are located in two adjacent rows.

Specifically, the aperture 50 includes a third aperture 503. For example, one part of an orthographic projection of the third aperture 503 onto the base substrate is located within the orthographic projection of the anode pattern 70 included in the blue sub-pixel B onto the base substrate. The other part of the orthographic projection of the third aperture 503 onto the base substrate does not overlap with the orthographic projection of the anode pattern 70 included in the blue sub-pixel B onto the base substrate. For example, a proportion of the one part is less than ⅓ of the entire third aperture 503. For example, a proportion of the one part is approximately ¼ of the entire third pore 503. For example, the third aperture 503 belongs to the blue sub-pixel B.

For example, the other part of the orthographic projection of the third aperture 503 onto the base substrate is located between the orthographic projection of the anode pattern 70 included in the blue sub-pixel B onto the base substrate and the orthographic projection of the anode pattern 70 included in second green sub-pixel G2 onto the base substrate. For example, the anode pattern 70 included in the second green sub-pixel G2 is located in a next row adjacent to the anode pattern 70 included in the blue sub-pixel B. For example, the anode pattern 70 included in the blue sub-pixel B and the anode pattern 70 included in the second green sub-pixel G2 are arranged along a fifth direction. The fifth direction intersects the first direction and the second direction.

In some embodiments, an area of one part of the orthographic projection of the third aperture onto the base substrate is less than 30% of an entire area of the orthographic projection of the third aperture onto the base substrate.

As shown in FIG. 16 to FIG. 19, in some embodiments, the multiple sub-pixels are divided into multiple pixel units. Each pixel unit includes a red sub-pixel R, a blue sub-pixel B, a first green sub-pixel G1 and a second green sub-pixel G2.

Among the pixel units located in the same row along the first direction, in each pixel unit, the anode pattern 70 included in the red sub-pixel R, the anode pattern 70 included in the blue sub-pixel B, and the anode pattern 70 included in the first green sub-pixel G1 are distributed in one row (e.g., labeled by X3); and the anode patterns 70 included in the second green sub-pixel G2 in each pixel unit are distributed in another row (e.g., labeled by X4).

The aperture 50 includes a fourth aperture 504. One part of an orthographic projection of the fourth aperture 504 onto the base substrate is located within the orthographic projection of the anode pattern included in the red sub-pixel R onto the base substrate.

The other part of the orthographic projection of the fourth aperture 504 onto the base substrate is located between the orthographic projection of the anode pattern included in the red sub-pixel R onto the base substrate and the orthographic projection of the anode pattern 70 included in second green sub-pixel G2 onto the base substrate. The anode pattern included in the red sub-pixel R and the anode pattern included in the second green sub-pixel G2 are located in two adjacent rows.

Specifically, the aperture 50 includes a fourth aperture 504. For example, one part of an orthographic projection of the fourth aperture 504 onto the base substrate is located within the orthographic projection of the anode pattern 70 included in the red sub-pixel R onto the base substrate. The other part of the orthographic projection of the fourth aperture 504 onto the base substrate does not overlap with the orthographic projection of the anode pattern 70 included in the red sub-pixel R onto the base substrate. For example, a proportion of the one part is less than ¾ of the entire fourth aperture 504. For example, the proportion of the one part is approximately ⅔ of the entire fourth aperture 504.

For example, the other part of the orthographic projection of the fourth aperture 504 onto the base substrate is located between the orthographic projection of the anode pattern 70 included in the red sub-pixel R onto the base substrate and the orthographic projection of the anode pattern 70 included in second green sub-pixel G2 onto the base substrate. For example, the anode pattern 70 included in the second green sub-pixel G2 is located in the next row adjacent to the anode pattern 70 included in the red sub-pixel R. For example, the fourth aperture 504 belongs to the green sub-pixel G.

In some embodiments, an area of one part of the orthographic projection of the fourth aperture onto the base substrate is less than 75% of an entire area of the orthographic projection of the fourth aperture onto the base substrate.

In the display substrate provided in the foregoing embodiment, when the first aperture 501, the second aperture 502, the third aperture 503 and the fourth aperture 504 are included, the light transmission of the display substrate can be maximized, thereby providing good conditions for the sensor to collect light signals and effectively improving speed and accuracy of fingerprint recognition.

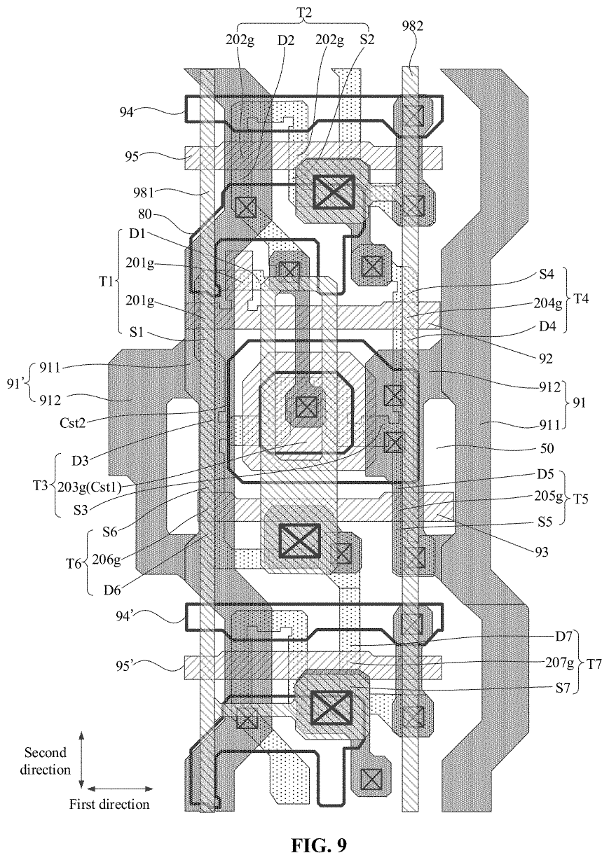

As shown in FIG. 10 and FIG. 25, in some embodiments, the main body portion 9120 includes a first main body part 9120a and a second main body part 9120b. The first main body part 9120a is close to the first end portion 9121. The second main body part 9120b is close to the second end portion 9122. In a plane parallel to the base substrate in a direction perpendicular to the second direction, a width L1 of the first main body part 9120a is greater than a width L2 of the second main body part 9120b.

The sub-pixel further includes a sub-pixel driving circuit. The sub-pixel driving circuit includes a driving transistor (i.e., a third transistor T3) and a storage capacitor Cst. A first electrode plate Cst1 of the storage capacitor Cst is coupled with a gate electrode of the driving transistor. An orthographic projection of a second electrode plate Cst2 of the storage capacitor Cst onto the base substrate overlaps with an orthographic projection of the first main body part 9120a onto the base substrate. The second electrode plate Cst2 of the storage capacitor Cst is coupled with the first main body part 9120a through a via-hole in an overlapping area of the orthographic projection of the second electrode plate Cst2 of the storage capacitor Cst onto the base substrate and the orthographic projection of the first main body part 9120a onto the base substrate.

Specifically, in the plane parallel to the base substrate and in the direction perpendicular to the second direction, the width L1 of the first main body part 9120a is greater than the width L2 of the second main body part 9120b, and the orthographic projection of the second electrode plate Cst2 of the storage capacitor Cst onto the base substrate overlaps with the orthographic projection of the first main body part 9120a onto the base substrate, so that a larger overlapping area is formed between the second electrode plate Cst2 of the storage capacitor Cst and the first main body part 9120a. in this way, when the second electrode plate Cst2 of the storage capacitor Cst is coupled with the first main body part 9120a through a via-hole in the overlapping area, layout difficulty of the via-hole can be reduced, and connection performance between the second electrode plate Cst2 of the storage capacitor Cst and the first main body part 9120a can be better improved.

As shown in FIG. 9 and FIG. 24, in some embodiments, the orthographic projection of the second electrode plate Cst2 of the storage capacitor Cst onto the base substrate does not overlap with the orthographic projection of the aperture 50 onto the base substrate.

Through above arrangement, the second electrode plate Cst2 of the storage capacitor Cst does not shield the aperture 50, thereby better ensuring the light transmittance of the aperture 50.

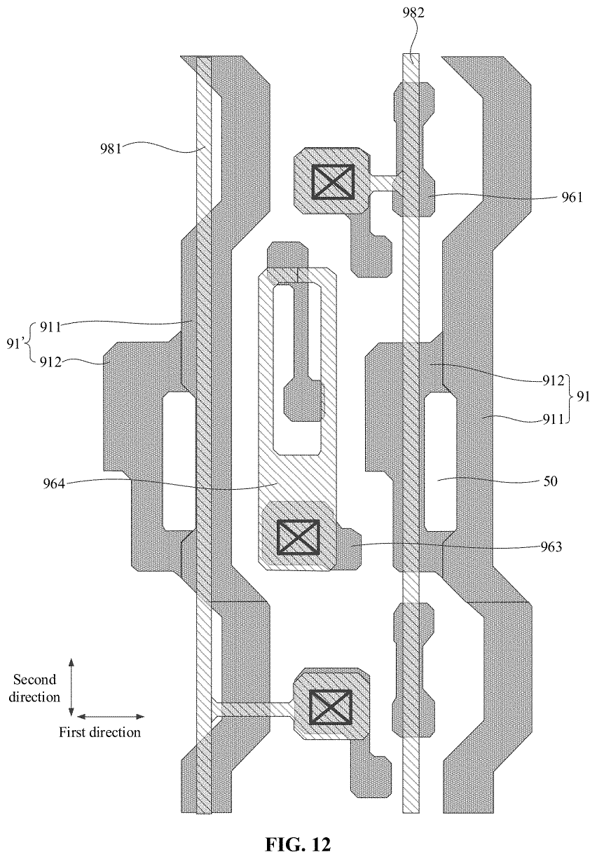

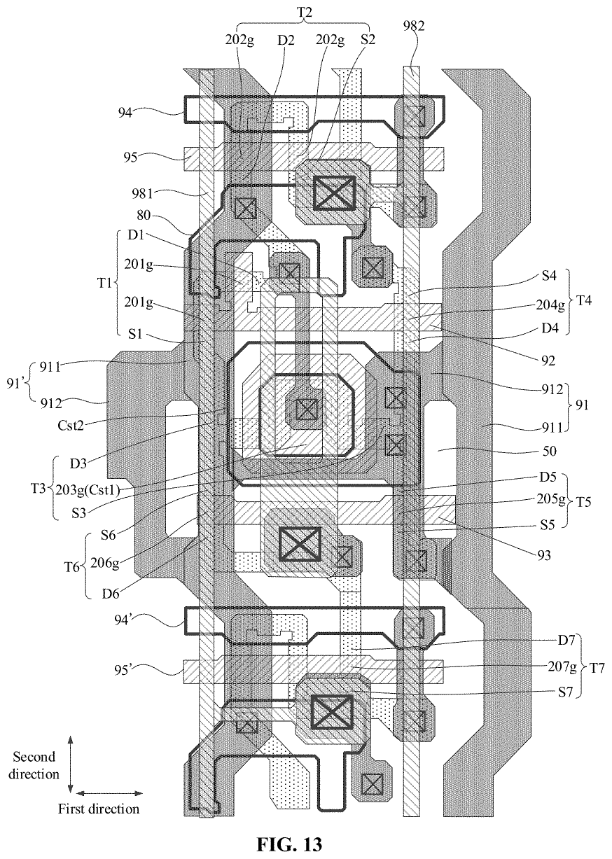

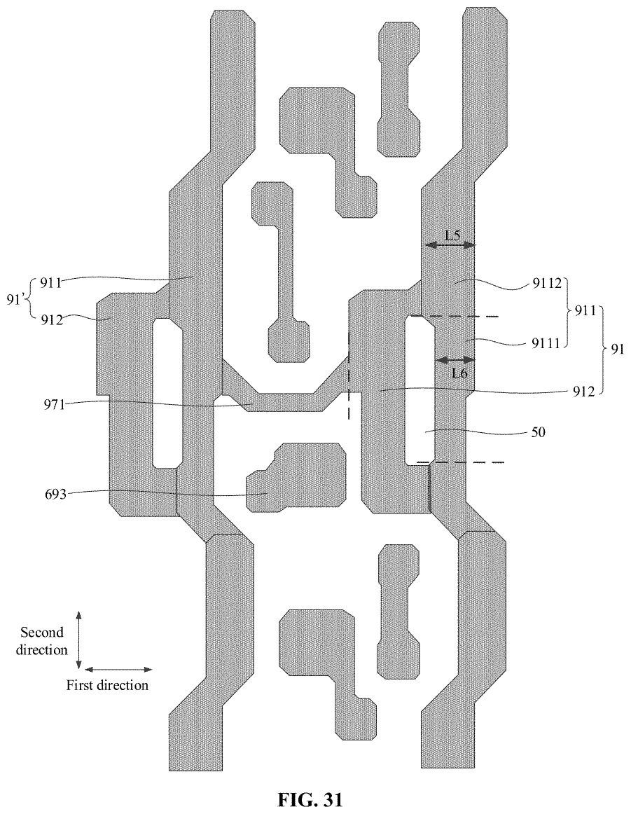

As shown in FIG. 13, FIG. 14, FIG. 30, and FIG. 31, in some embodiments, the sub-pixel further includes a power compensation pattern 971. At least one part of the power compensation pattern 971 extends along the first direction. The power compensation pattern 971 is respectively coupled with the main body portion 9120, and the first power line portion 911 of the sub-pixel, which is adjacent, in the first direction, to the sub-pixel to which the power compensation pattern 971 belongs.

For example, the power compensation pattern 971 is formed as an integral structure with the main body portion 9120 and the first power line portion 911.

The sub-pixel further includes the power compensation pattern 971, so that the power signal line patterns 91 included in the sub-pixels in the same row can be electrically connected together through the power compensation pattern 971, thereby reducing overall resistance of the power signal line patterns 91 and better improving display uniformity of the display substrate. Further, the first power line portions 911 in the sub-pixels in the same column are electrically connected in sequence, all the power signal line patterns 91 included in the display substrate are formed together into a mesh structure, thereby further improving the display uniformity of the display substrate.

As shown in FIG. 13 and FIG. 30, in some embodiments, the sub-pixel further includes: a reset signal line pattern 95, a gate line pattern 92, and a light-emitting control signal line pattern 93, which are sequentially distributed along the second direction. At least one part of the signal line pattern 95 extends along the first direction. At least one part of the gate line pattern 92 extends along the first direction. At least one part of the light-emitting control signal line pattern 93 extends along the first direction. An orthographic projection of the power compensation pattern 971 onto the base substrate is located between an orthographic projection of the gate line pattern 92 onto the base substrate and an orthographic projection of the light-emitting control signal line pattern 93 onto the base substrate.

Specifically, the sub-pixel further includes: a reset signal line pattern 95, a gate line pattern 92, and a light-emitting control signal line pattern 93 which are sequentially distributed along the second direction. The reset signal line is configured to transmit a reset signal. The gate line pattern 92 is configured to transmit a scan signal. The light-emitting control signal line pattern 93 is configured to transmit a light-emitting control signal.

At least one part of the reset signal line pattern 95 extends along the first direction. The reset signal line patterns 95 included in various sub-pixels located in the same row along the first direction are electrically connected in sequence to form an integral structure. At least one part of the gate line pattern 92 extends along the first direction. The gate line patterns 92 included in various sub-pixels located in the same row along the first direction are electrically connected in sequence to form an integral structure. At least one part of the light-emitting control signal line pattern 93 extends along a first direction. The light-emitting control signal line patterns 93 included in various sub-pixels located in the same row along the first direction are electrically connected in sequence to form an integral structure.

Specific layout positions of the power compensation pattern 971 are various. For example, an orthographic projection of the power compensation pattern 971 onto the base substrate does not overlap with an orthographic projection of the reset signal line pattern 95 onto the base substrate. The orthographic projection of the power compensation pattern 971 onto the base substrate does not overlap with the orthographic projection of the gate line pattern 92 onto the base substrate. The orthographic projection of the power compensation pattern 971 onto the base substrate does not overlap with the orthographic projection of the light-emitting control signal line pattern 93 onto the base substrate.

For example, the orthographic projection of the power compensation pattern 971 onto the base substrate is located between the orthographic projection of the gate line pattern 92 onto the base substrate and the orthographic projection of the light-emitting control signal line pattern 93 onto the base substrate.

For example, in the second direction, a minimum distance between the orthographic projection of the power compensation pattern 971 onto the base substrate and the orthographic projection of the gate line pattern 92 onto the base substrate, is greater than a minimum distance between the orthographic projection of the power compensation pattern 971 onto the base substrate and the orthographic projection of the light-emitting control signal line pattern 93 onto the base substrate.

For example, the minimum distance between the orthographic projection of the power compensation pattern 971 onto the base substrate and the orthographic projection of the light-emitting control signal line pattern 93 onto the base substrate, is greater than 5 μm.

When the power compensation pattern 971 is laid out in the above manner, there is long distance between the power compensation pattern 971 and each of the reset signal line pattern 95, the gate line pattern 92 and the light-emitting control signal line pattern 93, thereby avoiding to increase loads of the reset signal line pattern 95, the gate line pattern 92 and the light-emitting control signal line pattern 93.

As shown in FIG. 5, FIG. 13, FIG. 26 and FIG. 30, in some embodiments, the sub-pixel further includes a light-emitting control signal line pattern 93. At least one part of the light-emitting control signal line pattern 93 extends along the first direction. The light-emitting control signal line pattern 93 includes a first light-emitting control portion 931 and a second light-emitting control portion 932. An orthographic projection of the first light-emitting control portion 931 onto the base substrate overlaps with the orthographic projection of the main body portion 9120 onto the base substrate, the orthographic projection of the aperture 50 onto the base substrate and the orthographic projection of the first power line portion 911 onto the base substrate, respectively.

In the second direction, an orthographic projection of the second light-emitting control portion 932 onto the base substrate is opposite to the orthographic projection of the power compensation pattern 971 onto the base substrate. In a plane parallel to the base substrate and in a direction perpendicular to the first direction, a width L4 of the second light-emitting control portion 932 is smaller than a width L3 of the first light-emitting control portion 931.

Specifically, the light-emitting control signal line pattern 93 includes a first light-emitting control portion 931 and a second light-emitting control portion 932 that are coupled with each other. For example, the first light-emitting control portion 931 and the second light-emitting control portion 932 are formed as an integral structure.

In the second direction, an orthographic projection of the second light-emitting control portion 932 onto the base substrate is opposite to the orthographic projection of the power compensation pattern 971 onto the base substrate. In a plane parallel to the base substrate and in a direction perpendicular to the first direction, a width L4 of the second light-emitting control portion 932 is smaller than a width L3 of the first light-emitting control portion 931, so that a distance between the power compensation pattern 971 and the second light-emitting control portion 932 is larger, thereby better avoiding increasing the load of the light-emitting control signal line pattern 93.

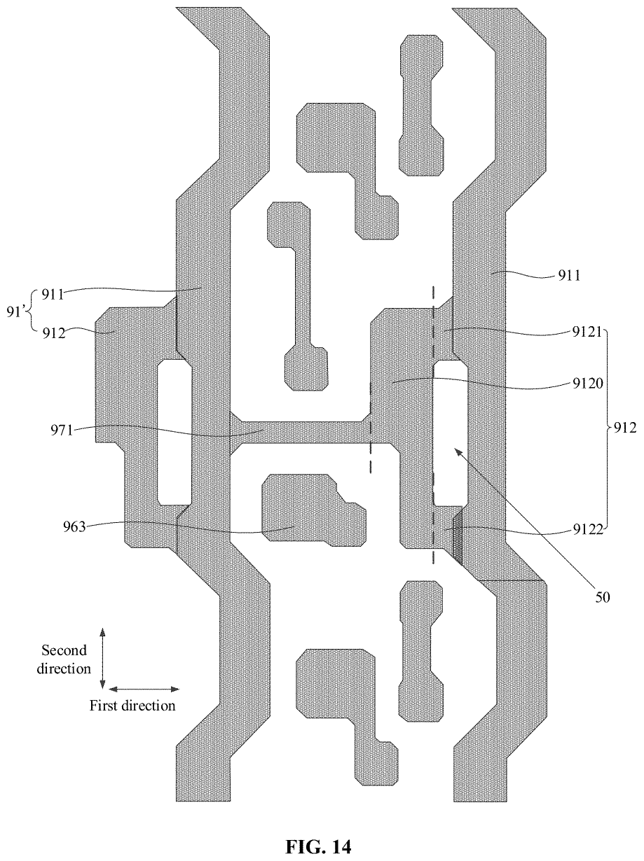

The specific structures of the power compensation pattern 971 are various. As shown in FIG. 14 and FIG. 15, in some embodiments, the power compensation pattern 971 is a strip structure which extends along the first direction.

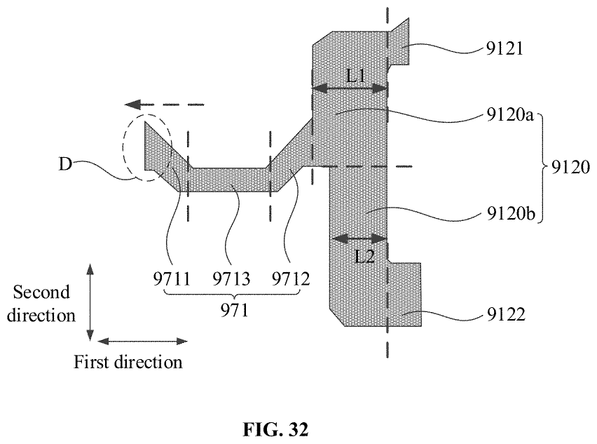

As shown in FIG. 31 and FIG. 32, in some embodiments, the power compensation pattern 971 includes a first portion 9711, a second portion 9712, and a third portion 9713. The first portion 9711 is coupled with the first power line portion 911 and one end of the third portion 9713, respectively. The second portion 9712 is respectively coupled with the main body portion 9120 and the other end of the third portion 9713. The third portion 9713 extends in the third direction. An extension direction of the first portion 9711 and an extension direction of the second portion 9712 both intersect each of the first direction and the second direction.

For example, the third portion 9713 extends along the first direction. An angle between the extension direction of the first portion 9711 and the first direction is 45 degrees. An angle between the extension direction of the second portion 9712 and the first direction is 45 degrees. The extension direction of the first portion 9711 is perpendicular to the extension direction of the second portion 9712.

The power compensation pattern 971 includes the first portion 9711, the second portion 9712, and the third portion 9713, so that the power compensation pattern 971 has a larger area, which is more conducive to reducing an overall resistance of the signal line pattern 91 and improving the display uniformity of the display substrate.

In addition, the power compensation pattern 971 includes the first portion 9711, the second portion 9712 and the third portion 9713, so that the power compensation pattern 971 can better avoid other conductive patterns on the same layer, thereby better reducing the layout difficulty of the power compensation pattern 971 and improving reliability of the display substrate.

As shown in FIG. 15 and FIG. 32, in some embodiments, in a plane parallel to the base substrate and in a direction perpendicular to the first direction, an end D of the power compensation pattern 971 directly coupled with the first power line portion 911 has a first width. The first width gradually increases in a direction close to the first power line portion 911 (e.g., a direction indicated by a dashed line with an arrow in FIG. 15 and FIG. 32).

Through above arrangement, the power compensation pattern 971 and the first power line portion 911 have better connection performance while avoiding the risk of static electricity caused by a right angle structure formed at the connection between the power compensation pattern 971 and the first power line portion 911.

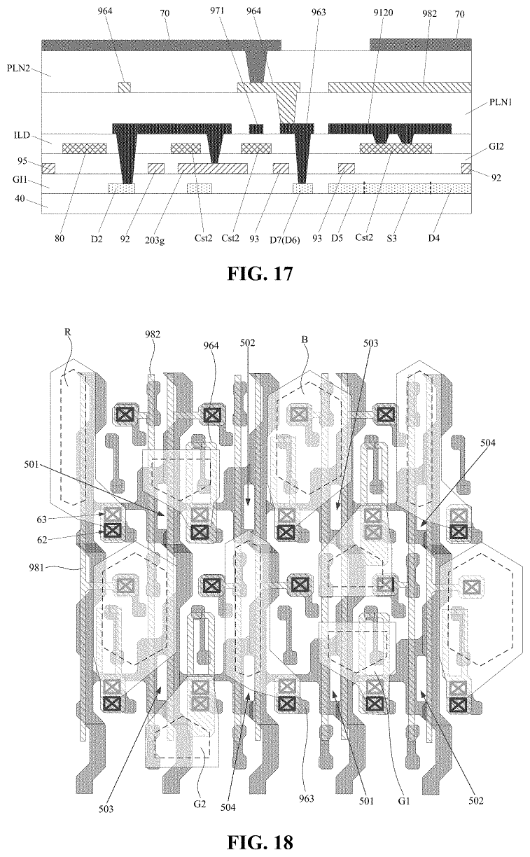

As shown in FIG. 18 and FIG. 33, in some embodiments, the sub-pixel further includes a light-emitting element. The light-emitting element includes an anode pattern 70. An orthographic projection of the anode pattern 70 onto the base substrate overlaps with an orthographic projection of the power compensation pattern 971 onto the base substrate.

Specifically, by setting the orthographic projection of the anode pattern 70 onto the base substrate to be overlapped with the orthographic projection of the power compensation pattern 971 onto the base substrate, it helps to improve flatness of the anode pattern and improve the color shift phenomenon of the display substrate.

As shown in FIG. 2, FIG. 9 and FIG. 24, in some embodiments, the sub-pixel further includes: a light-emitting element, an initialization signal line pattern 94, a reset signal line pattern 95, a gate line pattern 92, and a light-emitting control signal line pattern 93. At least one part of the initialization signal line pattern 94, at least one part of the reset signal line pattern 95, at least one part of the gate line pattern 92 and at least one part of the light-emitting control signal line pattern 93 all extend along the first direction.

The sub-pixel further includes:

a first data line pattern 981 and a second data line pattern 982 which are arranged oppositely along the first direction, where at least one part of the first data line pattern 981 and at least one part of the second data line pattern 982 extend along the second direction;

a sub-pixel driving circuit including: a first transistor T1, a second transistor T2, a third transistor T3, a fourth transistor T4, a fifth transistor T5, a sixth transistor T6, a seventh transistor T7, and a storage capacitor Cst.

A gate electrode of the third transistor T3 is coupled with a second electrode of the first transistor T1. A first electrode of the third transistor T3 is coupled with a second electrode of the fifth transistor T5. A second electrode of the third transistor T3 is coupled with the first electrode of the first transistor T1.

A gate electrode of the first transistor Ti is coupled with the gate line pattern 92;

A gate electrode of the second transistor T2 is coupled with the reset signal line pattern 95. A first electrode of the second transistor T2 is coupled with the initialization signal line pattern 94. A second electrode of the second transistor T2 is coupled with a gate electrode T3 of the third transistor T3.

A gate electrode of the fourth transistor T4 is coupled with the gate line pattern 92. A first electrode of the fourth transistor T4 is coupled with the first data line pattern 981 or the second data line pattern 982. A second electrode of the fourth transistor T4 is coupled with the first electrode of the third transistor T3.

A gate electrode of the fifth transistor T5 is coupled with the light-emitting control signal line pattern 93. A first electrode of the fifth transistor T5 is coupled with the power signal line pattern.

A gate electrode of the sixth transistor T6 is coupled with the light-emitting control signal line pattern 93. A first electrode of the sixth transistor T6 is coupled with the second electrode of the third transistor T3. A second electrode of the sixth transistor T6 is coupled with the light-emitting element.

A gate electrode of the seventh transistor T7 is coupled with the reset signal line pattern 95′ in the next adjacent sub-pixel in the second direction. A first electrode of the seventh transistor T7 is coupled with the initialization signal line pattern 94′ in the next adjacent sub-pixel in the second direction. A second electrode of the seventh transistor T7 is coupled with the light-emitting element.

A first electrode plate Cstl of the storage capacitor Cst is reused as the gate electrode of the third transistor T3. A second electrode plate Cst2 of the storage capacitor Cst is coupled with the power signal line pattern.

Specifically, each sub-pixel further includes a sub-pixel driving circuit. By taking one sub-pixel driving circuit as an example, the sub-pixel driving circuit includes 7 thin film transistors and 1 capacitor. Each transistor included in the sub-pixel driving circuit adopts a P-type transistor. A first electrode of each transistor includes a source electrode. A second electrode of each transistor includes a drain electrode. It should be noted that a power signal transmitted on the power signal line pattern 91 is a high-potential direct current signal. A signal transmitted on the negative power signal line VSS is a low-potential direct current signal. The initialization signal transmitted on the initialization signal line pattern 94 is a low-potential direct current signal.

A first transistor T1 has a dual-gate structure. A gate electrode 201g of the first transistor T1 is coupled with the gate line pattern 92. A source electrode Si of the first transistor T1 is coupled with a drain electrode D3 of a third transistor T3 (i.e., a driving transistor). A drain electrode D1 of the first transistor T1 is coupled with a gate electrode 203g of the third transistor T3.

A second transistor T2 has a dual-gate structure. A gate electrode 202g of the second transistor T2 is coupled with the reset signal line pattern 95. A source electrode S2 of the second transistor T2 is coupled with the initialization signal line pattern 94. A drain electrode D2 of the second transistor T2 is coupled with the gate electrode 203g of the third transistor T3.

A gate electrode 204g of a fourth transistor T4 is coupled with the gate line pattern 92. A source electrode S4 of the fourth transistor T4 is coupled with the first data line pattern 981 or the second data line pattern 982. A drain electrode D4 of the fourth transistor T4 is coupled with the source electrode S3 of the third transistor T3.

A gate electrode 205g of a fifth transistor T5 is coupled with the light-emitting control signal line pattern 93. A source electrode S5 of the fifth transistor T5 is coupled with the power signal line pattern 91. A drain electrode D5 of the fifth transistor T5 is coupled with the source electrode S3 of the third transistor T3.

A gate electrode 206g of a sixth transistor T6 is coupled with the light-emitting control signal line pattern 93. A source electrode S6 of the sixth transistor T6 is coupled with the drain electrode D3 of the third transistor T3. A drain electrode D6 of the sixth transistor T6 is coupled with an anode of the light-emitting element EL.

A gate electrode 207g of a seventh transistor T7 is coupled with the reset signal line pattern 95′ in the next sub-pixel adjacent in the second direction. A drain electrode D7 of the seventh transistor T7 is coupled with the anode of the corresponding light-emitting element EL. A source electrode S7 of the seventh transistor T7 is coupled with the initialization signal line pattern 94′ in the next sub-pixel adjacent in the second direction.

A first electrode plate Cst1 of a storage capacitor Cst is reused as the gate electrode 203g of the third transistor T3. A second electrode plate Cst2 of the storage capacitor Cst is coupled with the power signal line pattern 91.

As shown in FIG. 16 to FIG. 19, in some embodiments, the sub-pixel driving circuit further includes a sixth transistor T6. A first electrode of the sixth transistor T6 is coupled with a second electrode of the driving transistor (i.e., the third transistor).

The sub-pixel further includes a third conductive connection portion 963, a fourth conductive connection portion 964, and a light-emitting element that are sequentially stacked in a direction away from the base substrate. The light-emitting element includes an anode pattern 70.

There is a third overlapping area between an orthographic projection of the second electrode of the sixth transistor T6 onto the base substrate and an orthographic projection of the third conductive connecting portion 963 onto the base substrate. The second electrode of the sixth transistor T6 is coupled with the third conductive connection portion 963 in the third overlapping area.

There is a fourth overlapping area between the orthographic projection of the third conductive connecting portion 963 onto the base substrate and an orthographic projection of the fourth conductive connecting portion 964 onto the base substrate. The third conductive connecting portion 963 is coupled with the fourth conductive connecting portion 964 in the fourth overlapping area.

There is a fifth overlapping area between the orthographic projection of the fourth conductive connecting portion 964 onto the base substrate and the orthographic projection of the anode pattern onto the base substrate. The fourth conductive connecting portion 964 is coupled with the anode pattern in the fifth overlapping area.

For example, the sub-pixel driving circuit further includes a sixth transistor T6. A gate electrode of the sixth transistor T6 is coupled with the light-emitting control signal line pattern 93. A first electrode of the sixth transistor T6 is coupled with the second electrode of the driving transistor. There is a third overlapping area between an orthographic projection of the second electrode of the sixth transistor T6 onto the base substrate and an orthographic projection of the third conductive connecting portion 963 onto the base substrate. The second electrode of the sixth transistor T6 is coupled with the third conductive connection portion 963 through a first via-hole 61 in the third overlapping area.

There is a fourth overlapping area between the orthographic projection of the third conductive connecting portion 963 onto the base substrate and an orthographic projection of the fourth conductive connecting portion 964 onto the base substrate. The third conductive connecting portion 963 is coupled with the fourth conductive connecting portion 964 through a second via-hole 62 in the fourth overlapping area.

There is a fifth overlapping area between the orthographic projection of the fourth conductive connecting portion 964 onto the base substrate and the orthographic projection of the anode pattern 70 onto the base substrate. The fourth conductive connecting portion 964 is coupled with the anode pattern through a third via-hole 63 in the fifth overlapping area.

In the light-emitting period, the sixth transistor T6 transmits a driving signal output by the second electrode of the driving transistor to the anode pattern 70 of the light-emitting element through the third conductive connection portion 963 and the fourth conductive connection portion 964 in sequence.

In the display substrate provided in the foregoing embodiment, the second electrode of the sixth transistor T6 is coupled with the anode pattern through the third conductive connection portion 963 and the fourth conductive connection portion 964, thereby ensuring coupling performance between the second electrode of the sixth transistor T6 and the anode pattern.

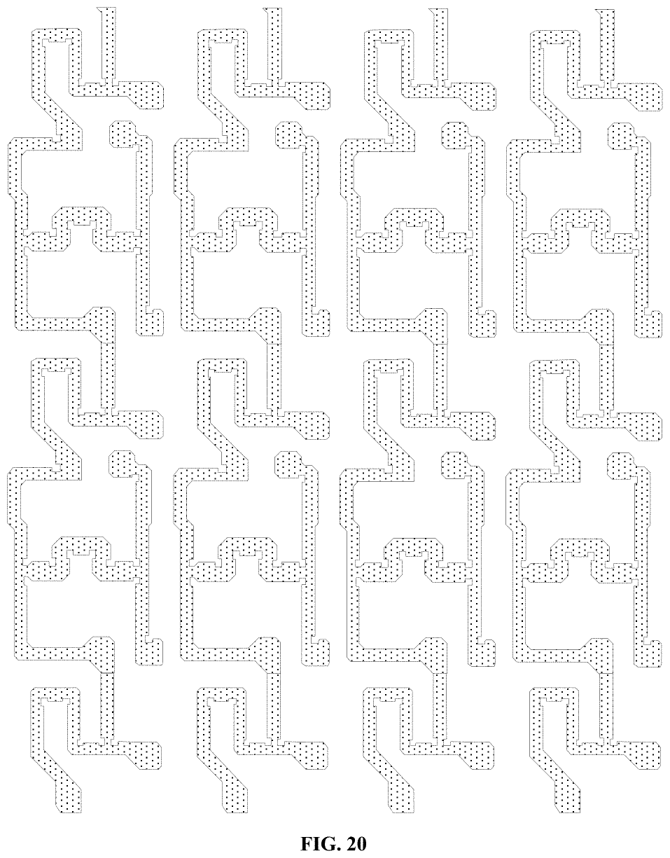

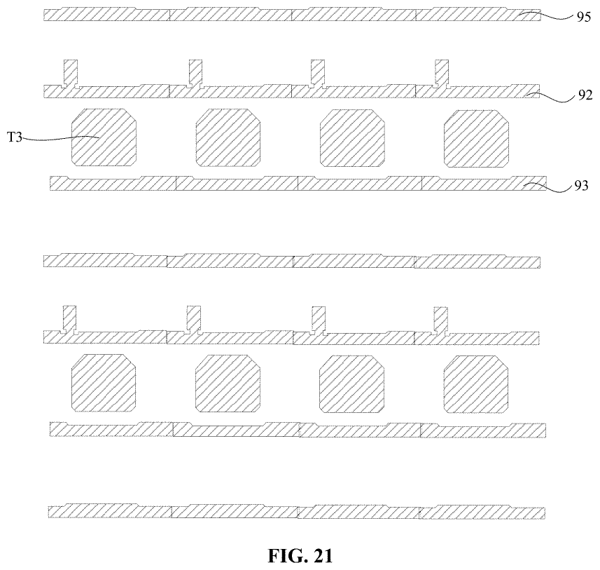

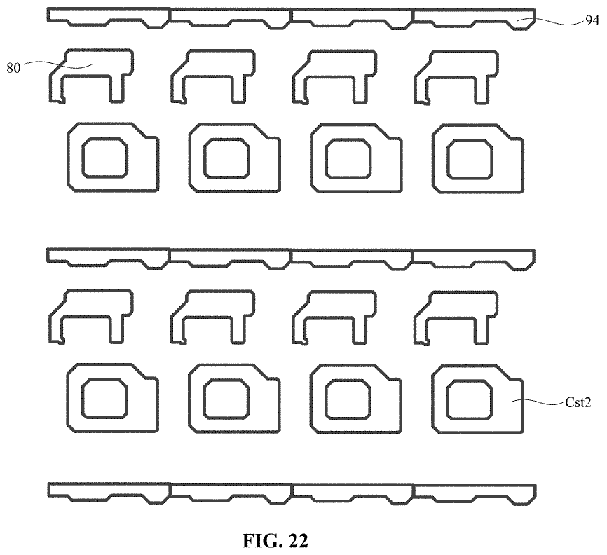

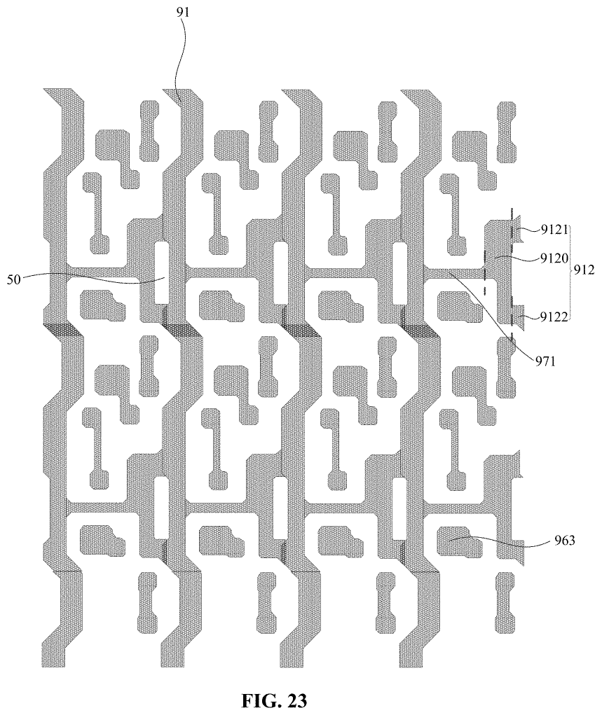

It should be noted that in the drawings provided in the present disclosure, a small box with crossed lines represents a via-hole. FIG. 4, FIG. 9 and FIG. 13 show the same active layer, first gate metal layer, second gate metal layer, and second source-drain metal layer. That is, FIG. 5 shows the active layer and the first gate metal layer of FIG. 4, FIG. 9 and FIG. 13; FIG. 6 shows the second gate metal layer of FIG. 4, FIG. 9 and FIG. 13; FIG. 8 shows the second source-drain metal layer of FIG. 4, FIG. 9 and FIG. 13. FIG. 20 shows a layout of the active layer in FIG. 16. FIG. 21 shows the first gate metal layer in FIG. 16. FIG. 22 shows the second gate metal layer in FIG. 16. FIG. 23 shows the first source-drain metal layer in FIG. 16.

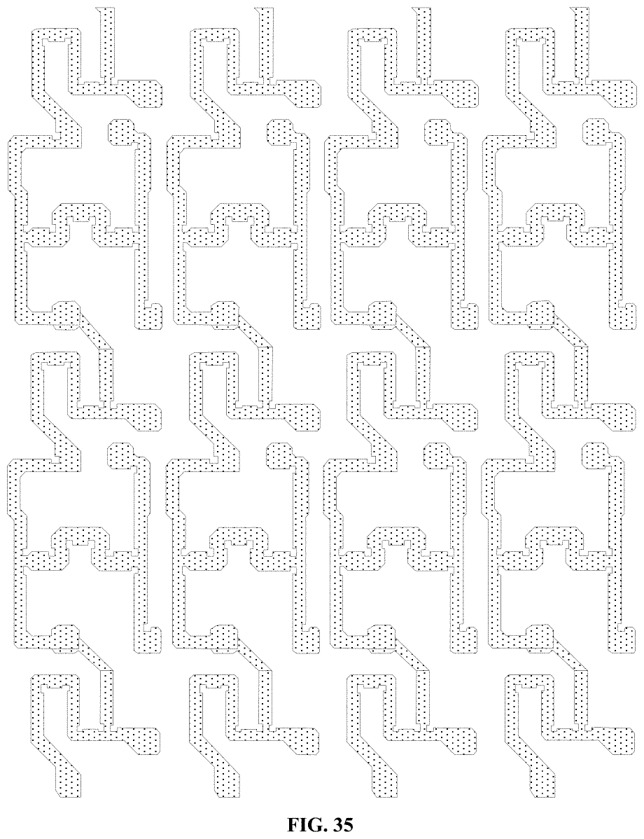

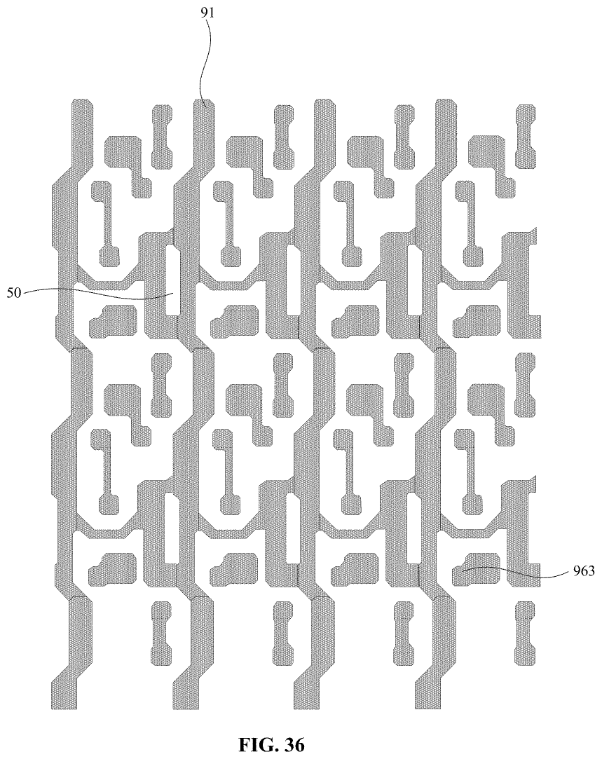

FIG. 24 and FIG. 30 show the same active layer, first gate metal layer, second gate metal layer, and second source-drain metal layer. That is, FIG. 26 shows the active layer and the first gate metal layer of FIG. 24 and FIG. 30; FIG. 28 shows the second gate metal layer of FIG. 24 and FIG. 30. It is worth noting that the layout of the second gate metal layer in FIG. 24 and FIG. 30 is basically the same as that in FIG. 6. FIG. 35 shows a layout of the active layer in FIG. 33. FIG. 36 shows a layout of the first source-drain metal layer in FIG. 33. FIG. 37 shows a layout of the second source-drain metal layer and the anode layer in FIG. 33.

One embodiments of the present disclosure further provides a display device, including the display substrate provided in the foregoing embodiments.

In the display substrate provided in the foregoing embodiments, the power signal line pattern 91 includes the first power line portion 911 and the second power line portion 912, so that the aperture 50 can be formed between the first power line portion 911 and the second power line portion 912, thereby reducing a proportion of an opaque area in the display substrate and improving the light transmittance of the display substrate. Therefore, when the display substrate provided in the foregoing embodiments is compatible with the optical fingerprint recognition technology, the display substrate can provide good conditions for the sensor to collect light signals, thereby effectively improving speed and accuracy of fingerprint recognition.

When the display device provided in the embodiment of the present disclosure includes the foregoing display substrate, it also has the foregoing beneficial effects, which will not be repeated here.

It should be noted that the display device may be any product or component with a display function, such as a television, a monitor, a digital photo frame, a mobile phone, a tablet computer, and so on.

One embodiments of the present disclosure further provides a method for manufacturing the display substrate provided in the foregoing embodiments. The method includes: fabricating sub-pixels arranged in an array on a base substrate. Steps of manufacturing the sub-pixels specifically include:

fabricating a power signal line pattern; where the power signal line pattern includes a first power line portion and a second power line portion; at least one part of the first power line portion extends in a second direction; the second power line portion includes a main body portion, a first end portion and a second end portion; the main body portion and the first power line portion are arranged in a first direction and are spaced apart from each other; the first direction intersects the second direction; the first end portion and the second end portion are disposed opposite to each other along the second direction; the first end portion is respectively coupled with one end of the main body portion and the first power line portion; the second end portion is respectively coupled with the other end of the main body portion and the first power line portion; an aperture is defined between the first power line portion and the second power line portion.

In the display substrate manufactured by the method provided in the embodiment of the present disclosure, the power signal line pattern 91 includes the first power line portion 911 and the second power line portion 912, so that the aperture 50 can be formed between the first power line portion 911 and the second power line portion 912, thereby reducing a proportion of an opaque area in the display substrate and improving the light transmittance of the display substrate. Therefore, when the display substrate manufactured by the method provided in the embodiment of the present disclosure is compatible with the optical fingerprint recognition technology, the display substrate can provide good conditions for the sensor to collect light signals, thereby effectively improving speed and accuracy of fingerprint recognition.

It should be noted that various embodiments in this specification are described in a progressive manner, and the same or similar parts between the various embodiments may be referred to each other. Each embodiment focuses on differences from other embodiments. In particular, for the method embodiment, since it is basically similar to the product embodiment, the description is relatively simple, and the relevant parts can be referred to the part of the description of the product embodiment.

Unless otherwise defined, any technical or scientific terms used herein shall have the common meaning understood by a person of ordinary skills. Such words as “first” and “second” used in the specification and claims are merely used to differentiate different components rather than to represent any order, number or importance. Such words as “comprises” or “include” mean that an element or object appearing before the word covers elements or objects listed after the word and their equivalents, but do not exclude other elements or objects. Similarly, such words as “connect” or “coupled” or “connected” may include electrical connection, direct or indirect, rather than being limited to physical or mechanical connection. Such words as “on/above”, “under/below”, “left” and “right” are merely used to represent relative position relationship, and when an absolute position of an object is changed, the relative position relationship will be changed too.

It will be understood that when an element such as a layer, film, region, or substrate is referred to as being “on” or “under” another element, this element may be “directly” on or “under” the other element, or, there may be an intermediate element therebetween.

In the description of the above embodiments, specific features, structures, materials or characteristics may be combined in any suitable manner in any one or more embodiments or examples.

The above are merely the embodiments of the present disclosure and shall not be used to limit the scope of the present disclosure. It should be noted that, a person skilled in the art may make improvements and modifications without departing from the principle of the present disclosure, and these improvements and modifications shall also fall within the scope of the present disclosure. The protection scope of the present disclosure shall be subject to the protection scope of the claims.

1. A display substrate, comprising: a base substrate and an array of sub-pixels on the base substrate;
wherein each sub-pixel includes a power signal line pattern;
the power signal line pattern includes a first power line portion and a second power line portion; at least one part of the first power line portion extends in a second direction; the second power line portion includes a main body portion, a first end portion and a second end portion; the main body portion and the first power line portion are arranged in a first direction and are spaced apart from each other; the first direction intersects the second direction; the first end portion and the second end portion are disposed opposite to each other along the second direction;
the first end portion is respectively coupled with one end of the main body portion and the first power line portion; the second end portion is respectively coupled with the other end of the main body portion and the first power line portion; an aperture is defined between the first power line portion and the second power line portion.

2. The display substrate according to claim 1, wherein the sub-pixels are divided into multiple rows of sub-pixels; each row of sub-pixels includes multiple sub-pixels arranged in sequence along the first direction; the sub-pixel further includes:
a first data line pattern and a second data line pattern arranged oppositely along the first direction;
at least one part of the first data line pattern and at least one part of the second data line pattern extend along the second direction;
an orthographic projection of the first data line pattern onto the base substrate, overlaps with an orthographic projection of the first power line portion in one sub-pixel, which is adjacent, in the first direction, to the sub-pixel that the first data line pattern belongs to, onto the base substrate;
an orthographic projection of the second data line pattern onto the base substrate overlaps with an orthographic projection of the main body portion onto the base substrate.

3. The display substrate according to claim 2, wherein the orthographic projection of the first data line pattern onto the base substrate does not overlap with an orthographic projection of the aperture onto the base substrate; and/or, the orthographic projection of the second data line pattern onto the base substrate does not overlap with the orthographic projection of the aperture onto the base substrate.

4. The display substrate according to claim 1, wherein the sub-pixel further includes a light-emitting control signal line pattern; at least one part of the light-emitting control signal line pattern extends along the first direction; an orthographic projection of the light-emitting control signal line pattern onto the base substrate partially overlaps with an orthographic projection of the aperture onto the base substrate.

5. The display substrate according to claim 1, wherein the first power line portion includes a second sub-portion and a first sub-portion that encloses the aperture;
in a plane parallel to the base substrate and in a direction perpendicular to the second direction, a width of the first sub-portion is less than a width of the second sub-portion.

6. The display substrate according to claim 1, wherein the sub-pixel further includes a light-emitting element; the light-emitting element includes an anode pattern; an orthographic projection of the anode pattern onto the base substrate does not overlap with an orthographic projection of the aperture onto the base substrate.

7. The display substrate according to claim 6, wherein the orthographic projection of the aperture onto the base substrate is between an orthographic projection of a first anode pattern onto the base substrate and an orthographic projection of a second anode pattern onto the base substrate; the sub-pixel to which the aperture belongs, includes the first anode pattern; and a next sub-pixel, which is adjacent to, in the first direction, the sub-pixel to which the aperture belongs, includes the second anode pattern.

8. The display substrate according to claim 7, wherein the sub-pixels are divided into multiple pixel units; each pixel unit includes a red sub-pixel, a blue sub-pixel and two green sub-pixels;
among the pixel units in the same row along the first direction, the anode pattern included in the red sub-pixel in each pixel unit and the anode pattern included in the blue sub-pixel in each pixel unit are distributed in one row; and the anode pattern included in the green sub-pixel in each pixel unit are distributed in another row;
among the pixel units in the same row along the first direction, the anode pattern included in the red sub-pixel, the anode pattern included in the blue sub-pixel and the anode pattern included in the green sub-pixel are alternately distributed in sequence;
among the pixel units in the same row along the first direction, one of adjacent red sub-pixel and green sub-pixel includes the first anode pattern, and the other of the adjacent red sub-pixel and green sub-pixel includes the second anode pattern;
among the pixel units in the same row along the first direction, one of adjacent blue sub-pixel and green sub-pixel includes the first anode pattern, and the other of the adjacent blue sub-pixel and green sub-pixel includes the second anode pattern.

9. The display substrate according to claim 1, wherein the sub-pixel further includes a light-emitting element; the light-emitting element includes an anode pattern; an orthographic projection of some anode patterns onto the base substrate overlaps with an orthographic projection of the aperture onto the base substrate.

10. The display substrate according to claim 1, wherein the main body portion includes a first main body part and a second main body part; the first main body part is close to the first end portion; the second main body part is close to the second end portion; in a plane parallel to the base substrate and in a direction perpendicular to the second direction, a width of the first main body part is greater than a width of the second main body part;
the sub-pixel further includes a sub-pixel driving circuit; the sub-pixel driving circuit includes a driving transistor and a storage capacitor; a first electrode plate of the storage capacitor is coupled with a gate electrode of the driving transistor; there is an overlapping area between an orthographic projection of a second electrode plate of the storage capacitor onto the base substrate and an orthographic projection of the first main body part onto the base substrate;
the second electrode plate of the storage capacitor is coupled with the first main body part through a via-hole in the overlapping area.

11. The display substrate according to claim 10, wherein the orthographic projection of the second electrode plate of the storage capacitor onto the base substrate does not overlap with an orthographic projection of the aperture onto the base substrate.

12. The display substrate according to claim 1, wherein the sub-pixel further includes a power compensation pattern; at least one part of the power compensation pattern extends along the first direction; the power compensation pattern is respectively coupled with the main body portion, and the first power line portion of one sub-pixel, which is adjacent, in the first direction, to the sub-pixel to which the power compensation pattern belongs.

13. The display substrate according to claim 12, wherein the sub-pixel further includes: a reset signal line pattern, a gate line pattern, and a light-emitting control signal line pattern, which are sequentially distributed along the second direction; at least one part of the signal line pattern extends along the first direction; at least one part of the gate line pattern extends along the first direction; at least one part of the light-emitting control signal line pattern extends along the first direction;
an orthographic projection of the power compensation pattern onto the base substrate is between an orthographic projection of the gate line pattern onto the base substrate and an orthographic projection of the light-emitting control signal line pattern onto the base substrate.

14. The display substrate according to claim 12, wherein the sub-pixel further includes a light-emitting control signal line pattern; at least one part of the light-emitting control signal line pattern extends along the first direction; the light-emitting control signal line pattern includes a first light-emitting control portion and a second light-emitting control portion;
an orthographic projection of the first light-emitting control portion onto the base substrate overlaps with an orthographic projection of the main body portion onto the base substrate, an orthographic projection of the aperture onto the base substrate and an orthographic projection of the first power line portion onto the base substrate, respectively;
in the second direction, an orthographic projection of the second light-emitting control portion onto the base substrate is opposite to an orthographic projection of the power compensation pattern onto the base substrate; in a plane parallel to the base substrate and in a direction perpendicular to the first direction, a width of the second light-emitting control portion is smaller than a width of the first light-emitting control portion.

15. The display substrate according to claim 12, wherein the power compensation pattern includes a first portion, a second portion, and a third portion; the first portion is coupled with the first power line portion and one end of the third portion, respectively;
the second portion is respectively coupled with the main body portion and the other end of the third portion; the third portion extends in the third direction; an extension direction of the first portion and an extension direction of the second portion both intersect each of the first direction and the second direction.

16. The display substrate according to claim 12, wherein in a plane parallel to the base substrate and in a direction perpendicular to the first direction, an end of the power compensation pattern coupled with the first power line portion has a first width; the first width gradually increases in a direction close to the first power line portion.

17. The display substrate according to claim 12, wherein the sub-pixel further includes a light-emitting element; the light-emitting element includes an anode pattern; an orthographic projection of the anode pattern onto the base substrate overlaps with an orthographic projection of the power compensation pattern onto the base substrate.

18. The display substrate according to claim 1, wherein the sub-pixel further includes: a light-emitting element, an initialization signal line pattern, a reset signal line pattern, a gate line pattern, and a light-emitting control signal line pattern; at least one part of the initialization signal line pattern, at least one part of the reset signal line pattern, at least one part of the gate line pattern and at least one part of the light-emitting control signal line pattern all extend along the first direction;
the sub-pixel further includes:
a first data line pattern and a second data line pattern which are arranged oppositely along the first direction, wherein at least one part of the first data line pattern and at least one part of the second data line pattern extend along the second direction;
a sub-pixel driving circuit including: a first transistor, a second transistor, a third transistor, a fourth transistor, a fifth transistor, a sixth transistor, a seventh transistor, and a storage capacitor;
a gate electrode of the third transistor is coupled with a second electrode of the first transistor; a first electrode of the third transistor is coupled with a second electrode of the fifth transistor; a second electrode of the third transistor is coupled with the first electrode of the first transistor;
a gate electrode of the first transistor is coupled with the gate line pattern;
a gate electrode of the second transistor is coupled with the reset signal line pattern;
a first electrode of the second transistor is coupled with the initialization signal line pattern; a second electrode of the second transistor is coupled with a gate electrode of the third transistor;
a gate electrode of the fourth transistor is coupled with the gate line pattern; a first electrode of the fourth transistor is coupled with the first data line pattern or the second data line pattern; a second electrode of the fourth transistor is coupled with the first electrode of the third transistor;
a gate electrode of the fifth transistor is coupled with the light-emitting control signal line pattern; a first electrode of the fifth transistor is coupled with the power signal line pattern;
a gate electrode of the sixth transistor is coupled with the light-emitting control signal line pattern; a first electrode of the sixth transistor is coupled with the second electrode of the third transistor; a second electrode of the sixth transistor is coupled with the light-emitting element;
a gate electrode of the seventh transistor is coupled with the reset signal line pattern in one next adjacent sub-pixel in the second direction; a first electrode of the seventh transistor is coupled with the initialization signal line pattern in the next adjacent sub-pixel in the second direction; a second electrode of the seventh transistor is coupled with the light-emitting element;
a first electrode plate of the storage capacitor is reused as the gate electrode of the third transistor; a second electrode plate of the storage capacitor is coupled with the power signal line pattern.

19. A display device, comprising:
a display substrate;
wherein the display substrate includes: a base substrate and an array of sub-pixels on the base substrate;
wherein each sub-pixel includes a power signal line pattern;
the power signal line pattern includes a first power line portion and a second power line portion; at least one part of the first power line portion extends in a second direction; the second power line portion includes a main body portion, a first end portion and a second end portion; the main body portion and the first power line portion are arranged in a first direction and are spaced apart from each other; the first direction intersects the second direction; the first end portion and the second end portion are disposed opposite to each other along the second direction;
the first end portion is respectively coupled with one end of the main body portion and the first power line portion; the second end portion is respectively coupled with the other end of the main body portion and the first power line portion; an aperture is defined between the first power line portion and the second power line portion.

20. A method for manufacturing a display device, comprising:
fabricating sub-pixels arranged in an array on a base substrate;
the fabricating sub-pixels includes:
fabricating a power signal line pattern; wherein the power signal line pattern includes a first power line portion and a second power line portion; at least one part of the first power line portion extends in a second direction; the second power line portion includes a main body portion, a first end portion and a second end portion; the main body portion and the first power line portion are arranged in a first direction and are spaced apart from each other; the first direction intersects the second direction; the first end portion and the second end portion are disposed opposite to each other along the second direction; the first end portion is respectively coupled with one end of the main body portion and the first power line portion; the second end portion is respectively coupled with the other end of the main body portion and the first power line portion; an aperture is defined between the first power line portion and the second power line portion.
